(19) United States
(12) Patent Application Publication
(10) Pub. No.: US 2005/0189622 A1
(43) Pub. Date: Sep. 1, 2005

(54) Packaged acoustic and electromagnetic transducer chips

(75) Inventors: Giles Humpston, San Jose, CA (US); Philip R. Osborn, Mountain View, CA (US); Jesse Burl Thompson, Brentwood, CA (US); Yoichi Kubota, Pleasanton, CA (US); Chung-Chuan Tseng, San Jose, CA (US); Robert Burtzlaff, Santa Clara, CA (US); Belgacem Haba, Cupertino, CA (US); David B. Tuckerman, Orinda, CA (US); Michael Warner, San Jose, CA (US)

Correspondence Address: LERNER DAVID, LITENBERG, KRUMHOLZ & MENTLIK, 600 SOUTH AVENUE WEST, WESTFIELD, NJ, 07090, US

(73) Assignee: Tessera, Inc., San Jose, CA (US)

(21) Appl. No.: 11/068,830

(22) Filed: Mar. 1, 2005

Related U.S. Application Data
(60) Provisional application No. 60/561,210, filed on Apr. 9, 2004.
(60) Provisional application No. 60/568,041, filed on May 4, 2004.
(60) Provisional application No. 60/574,523, filed on May 26, 2004.
(60) Provisional application No. 60/549,176, filed on Mar. 1, 2004.

(51) Int. Cl. H01L 23/495

(52) U.S. Cl. 257/659

(57) ABSTRACT

Various embodiments of packaged chips and ways of fabricating them are disclosed herein. One such packaged chip disclosed herein includes a chip having a front face, a rear face opposite the front face, and a device at one of the front and rear faces, the device being operable as a transducer of at least one of acoustic energy and electromagnetic energy, and the chip including a plurality of bond pads exposed at one of the front and rear faces. The packaged chip includes a package element having a dielectric element and a metal layer disposed on the dielectric element, the package element having an inner surface facing the chip and an outer surface facing away from the chip. The metal layer includes a plurality of contacts exposed at at least one of the inner and outer surfaces, the contacts conductively connected to the bond pads. The metal layer further includes a first opening for passage of the at least one of acoustic energy and electromagnetic energy in a direction of at least one of to said device and from said device.

### CROSS-REFERENCE TO RELATED APPLICATIONS

This application claims the benefit of the filing dates of U.S. Provisional Patent Application Nos. 60/549,176 filed Mar. 1, 2004; 60/561,210 filed Apr. 9, 2004; 60/568,041 filed May 4, 2004; and 60/574,523 filed May 26, 2004, the disclosures of all such applications being hereby incorporated herein by reference.

### BACKGROUND OF THE INVENTION

The present invention relates to the packaging of microstructure elements such as integrated circuit chips, micro-electromechanical device chips and other types of chips.

Certain types of chips require packaging that is open to the transmission of energy to and/or from outside the package. A microphone is one example. A microphone is a transducing device that converts acoustic pressure waves into electrical form. There exist many different types of microphones. One of the more common designs, favored on account of its combination of sensitivity, small physical dimensions and low power consumption, uses a parallel plate capacitor as the transducing element. If one of the two plates of a parallel plate capacitor is made flexible such that the plate deforms in response to an acoustic pressure wave, the deformation changes the spacing between the plates of the capacitor, causing a change in the capacitance which can be detected and converted to an electrical signal. In the case of an electret microphone, a change in the amount of charge stored on the capacitor is detected and converted to an electrical signal.

Recent advances in silicon processing technology now permit the manufacture of microphones directly on silicon wafers. Because a microphone has a moving element, these highly miniaturized devices are often referred to as micro-electromechanical system (MEMS) microphones. If the silicon wafer used to fabricate the microphone is of semiconductor device grade, this allows amplifiers, and other electronic devices to be incorporated on a chip in close proximity to a MEMS microphone on the same chip. Such construction offers improved sensitivity, better frequency response, lower noise floor, reduced component dimensions and lower manufacturing costs. Similarly, other sensing devices may incorporate MEMS devices to sense or measure physical phenomena.

The packaging of MEMS microphones and other devices that require cavities poses challenges. A package for a microphone requires an acoustic opening to allow acoustic pressure waves to reach one side of the movable plate of the parallel plate transducing element. The package must also provide an acoustic cavity on the opposite side of the movable plate so that the incident pressure wave will cause the movable plate to move and spring back relative to the other fixed plate. The packaged microphone must also meet requirements of semiconductor devices for reliability and ability to be integrated with other components on a printed circuit board using surface mount technology.

Other devices that require packages that have openings or cavities include devices that sense particulates, such as smoke detectors. Still other devices requiring such packaging include devices that detect the presence of gases, toxic chemicals, or liquids. These devices require that the material that is detected be able to reach a detecting device within the package.

One of the more challenging aspects of constructing such packages is to provide an interior cavity that exhibits the qualities required by a device, such as the acoustic cavity used in a package containing a microphone. In the example of a MEMS microphone, the size of the cavity within the package depends on the design and size of the microphone itself. Typically, the required size is an order of magnitude larger than the volume of the air gap between the fixed and moving plates of the parallel plate capacitor microphone. MEMS microphones can be provided on a silicon chip measuring about 2 mm by 2 mm in area, having a very small capacitor plate spacing, for example, having a spacing as small as about 0.5 μm in some cases. However, semiconductor device packages typically have larger dimensions, e.g., usually at least 5 mm on each side. The small 2 mm wide microphone chips cannot be packaged according to packaging technology provided for such larger size chips, such that microphones are fabricated on larger chips in order to accommodate the packaging technology. One of the challenges today is to provide an improved packaging technology that mates with smaller size microphone chips, thereby achieving reductions in the cost of fabricating and packaging chips.

One current concern regarding most microelectronic and MEMS chips such as acoustic transducer chips is that when packaged, the chip is designed to be mounted only in one orientation relative to a printed circuit board. For example, the “gull-wing” style packaged chip 10 shown in FIG. 1 is designed only to be mounted with the top 12 of the package facing up and away from the circuit board 14. Leads 16, called “S”-shaped leads, or simply “S-leads”, extend downwardly from the sides of the package and are bonded to bond pads 18 such as by solder masses 20. Such attachment of a packaged chip to bond pads 18 exposed at the surface of a circuit board 14 or other circuit panel is called “surface mounting”. In an exemplary structure, the chip 22 is bonded to a bottom portion 24 of the package through an adhesive material commonly used for that purpose called “die attach” 26. Wire bonds 28 electrically connect bond pads 30 of the chip to package ends 32 of the leads 16. A top portion of the package 34 is then mounted to the bottom portion 24 so as to enclose the chip 22 within the package.

The packaging technology shown in FIG. 1 does not allow for mounting in different orientations as is desirable for providing a packaged product to a number of different end users whose requirements can vary. The packaged chip 10 cannot be mounted in a position other than that shown in FIG. 1. It cannot be mounted in an inverted position in which the top portion 34 of the package faces the circuit board 14, unless a recess or opening is specially created in the circuit board to accommodate the different position.

In the case of acoustic transducer chips such as MEMS microphones, the opening of the package must generally be oriented in a direction towards the source of the pressure waves to be detected. For this reason, a packaged chip capable of being mounted to a circuit board in either a face-up or face-down orientation is a must in order for the packaged chip to find use in a maximum number of applications.

FIGS. 2 and 3 show examples of packaged acoustic transducer chips 50 and 60, respectively, which are capable of being mounted to a circuit board in only one orientation. In the “J-lead” package 50 shown in FIG. 2, an opening 51 in a top panel 52 of the package provides an acoustic port allowing pressure waves to pass to and/or from an acoustic transducer 54 on a chip 55. The chip 55 is wire-bonded to the J-leads 56, which in turn are conductively bonded, e.g., soldered, to terminals 57 of circuit board 58. In the “surface-mount” package 60 shown in FIG. 3, electrical connection is provided from a chip 64 through soldered interconnects 63 which conductively connect to a top panel 61 of the package. The soldered interconnects, in turn, are connected by traces and vias through the top panel 61 to a plurality of contacts 62 which are conductively connected by solder balls 67 to terminals 69 of a circuit panel 65. Further interconnection on the circuit panel is provided through traces 66 which are connected to the terminals 64. The surface-mount package 60 shown in FIG. 3 varies from the package 50 shown in FIG. 2 in that it is designed to be mounted such that the acoustic port 68 in the package is aligned with an opening 70 in the circuit panel 65. However, if one needed to mount the packaged chip 60 instead in a different orientation which faces away from the circuit board 65, this would not be possible, because of the lack of conductive interconnects provided on the exterior bottom side 72 of the packaged chip.

An image transducer chip receives or transmits through free space an image signal having electromagnetic energy at particular frequencies or wavelengths of interest, e.g., at optical wavelengths of interest. For that reason, image transducer chips also require packaging that is transparent to radiation at those particular frequencies or wavelengths. However, image transducer chips are subject to being easily contaminated. For that reason, image transducer chips typically require the opening through which the image signal passes to be covered with a material that is transparent to the image signal.

A particular challenge of packaging image transducer chips is mismatch between the coefficient of thermal expansion (CTE) of the chip, and the transparent material that covers the opening of a packaged image transducer chip. A circuit panel such as an printed circuit board of the FR-4 (reinforced fiberglass) type, to which the packaged chip is connected, typically has a CTE very different from that of a chip. For example, silicon has a CTE of roughly 2 ppm/deg. K, while printed circuit boards typically have a CTE of about 10 ppm/deg. K. Transparent covering materials have CTEs that range from low values to values comparable to those of printed circuit boards. A strain relieving mechanism is needed to permit the chip, having one CTE to be packaged together with a transparent covering material having a different CTE.

In addition, it is desirable to provide a way of packaging microstructures such as image transducers in low-profile packages. For example, it would be desirable to package an image transducer chip in a way that it can be easily inserted into a patient's mouth for recording a dental X-ray image.

### SUMMARY OF THE INVENTION

Various embodiments of packaged chips and ways of fabricating them are provided herein. According to one aspect of the invention, a packaged chip is provided which includes a chip having a front face, and a rear face opposite the front face. The chip includes a device at one of the front and rear faces, the device being operable as a transducer of at least one of acoustic energy and electromagnetic energy. The chip further includes a plurality of bond pads exposed at one of the front and rear faces. The packaged chip also includes a package element having a dielectric element and a metal layer disposed on the dielectric element. The package element has an inner surface facing the chip and an outer surface facing away from the chip. The metal layer includes a plurality of contacts exposed at at least one of the inner and outer surfaces, the contacts being conductively connected to the bond pads. The metal layer further includes a first opening for passage of the at least one of acoustic energy and electromagnetic energy in a direction of at least one of to the device and from the device.

In one preferred embodiment, the package element is flexible, the flexible package element having a flexible dielectric element. In such case, the flexible dielectric element preferably includes a second opening aligned to the first opening.

As examples of acoustic transducers, the transducer may have a pickup function, a loudspeaker function, or an accelerometer function, fore example, which may include a piezoelectric device.

In one embodiment, the transducer includes a capacitor. Such capacitor has first and second plates, wherein the first plate is movable by acoustic energy in relation to the second plate.

According to a preferred aspect of the invention, a package element having a flexible dielectric element includes a unitary metal sheet, the unitary metal sheet including both the metal layer in which the contacts are formed and traces extending from the contacts, as well as a unitary portion, and the unitary portion at least substantially surrounds the contacts and the traces.

According to another preferred aspect of the invention in which the package element is flexible, the bond pads of the chip are exposed at the front face. The flexible package element is folded such that a top portion of the flexible package element overlies the front face of the chip and a bottom portion of the flexible package element underlies the rear face. The contacts of the package element include bottom contacts exposed at the outer surface of the bottom portion. The flexible package element further includes leads, and the leads conductively connect the bond pads to the bottom contacts.

According to one preferred aspect of the invention, an assembly is provided which includes the packaged chip and a circuit panel mounted to the bottom contacts. The circuit panel may further include top contacts exposed at the outer surface of the top portion, such leads which may include one or more conductive elements, e.g., wire bonds.

In a particular preferred embodiment, the metal layer includes traces, and the traces include lead portions which are integral with the bottom terminals.

According to one preferred aspect of the invention in which the packaged chip includes a folded flexible package element, a spacer element is included for maintaining a spacing between the top portion and the bottom portion of the folded package element. The spacer element may include, for example, a compliant member bonded to the top portion and the bottom portion, and the compliant member may include a portion underlying the rear face of the chip.

In a packaged chip according to another preferred aspect of the invention, the package element includes an extended portion extending beyond a first peripheral edge of the chip, the extended portion having an inner surface facing toward the chip and an outer surface facing away from the chip. According to such preferred aspect, the extended portion includes at least one contact exposed at the inner surface for permitting conductive interconnection to the chip.

In a particular preferred embodiment, the contacts are exposed at the outer surface, and the package element has a plurality of lands exposed at the inner surface and traces extending between the lands and the contacts. In such embodiment, the packaged chip may further include conductive interconnects which extend between the bond pads and the lands.

In yet another preferred embodiment, the packaged chip can include a metal can which substantially encloses the chip. Preferably, the metal can is bonded to the package element, such that the metal layer and the metal can form a cavity adjacent to one of the front face and the rear face of the chip. In such case, the metal layer together with the metal can function as an electromagnetic shield at a frequency of interest.

In yet another preferred embodiment of the invention, the packaged chip can further include a housing which surrounds the peripheral edges of the chip. In this embodiment, the housing has a bottom surface bonded to the inner surface of the package element and the packaged chip further includes a metal lid overlying the chip, the metal lid being bonded to a top surface of the housing. In such case, the housing and the metal lid enclose a cavity adjacent to one of the front and rear faces of the chip.

According to another aspect of the invention, a packaged chip is provided which includes a chip, and a package element conductively connected to the chip via a plurality of conductive interconnects. The chip has a front face, a rear face opposite the front face, and has an acoustic transducer exposed at at least one of the front and rear faces, as well as a plurality of bond pads exposed at at least one of the front and rear faces. The package element has a plurality of through holes which are aligned to the bond pads. The package element is mounted to cover one of the front and rear faces of the chip so as to define a cavity between the acoustic transducer and the package element, leaving exposed another one of the front and rear faces for passage of acoustic energy to or from the acoustic transducer in a direction normal to the front face. In this embodiment, the electrically conductive interconnects extend at least partially through the through holes in the package element.

In a preferred embodiment, an assembly is provided which includes such packaged chip, the assembly which may further include a circuit panel having a plurality of terminals. The conductive interconnects are conductively bonded to the terminals, such that the exposed one of the front and rear faces faces away from the circuit panel to permit passage of the acoustic energy to and from the acoustic transducer.

According to a further preferred embodiment, the device may be such that its operation be alterable by electromagnetic energy which is able to reach the device-bearing face of the package element. For example, the device may include an ultra-violet light erasable programmable read only memory (UV-EPROM), the UV-EPROM being erasable by the electromagnetic energy. In another example, the device may include a fusible element which is permanently alterable by the electromagnetic energy.

In a particular embodiment of the invention, a packaged chip is provided in which the metal layer of the package element has a first opening and a cover member aligned to the first opening. In such embodiment, the cover member is mounted to at least one of the inner surface and the outer surface, and the cover member is substantially transparent to the electromagnetic energy to permit such energy to pass through to or from the device. As examples of the cover member, it can include one or more of an anti-reflective member, a scratch-resistant member, and a lens, or one element or a combination of elements having these functions.

In such embodiment, a preferred way is for the metal layer to be exposed at the inner surface of the package element, and the cover member be mounted to the metal layer.

In a particular embodiment, the device may include a first array of photosensitive elements, and the packaged chip include a photo-scintillator element aligned to the first opening. In such embodiment, the first array is operable to receive a first signal, the first signal being representative of a second signal incident on the photo-scintillator element. For example, the second signal can include X-ray wavelengths, the photo-scintillator element being in a position to receive the second signal, and generate the first signal which then strikes the first array of photosensitive elements on the device. Preferably, the photo-scintillator element is disposed between the inner surface of the package element and the chip. In one embodiment, the dielectric element can cover or substantially cover the first opening. In such case, the dielectric element need only be substantially transparent to the X-ray wavelengths, but can be substantially opaque to optical wavelengths.

According to another aspect of the invention, a packaged chip is provided which includes a chip and a package element mounted to the chip. In such packaged chip, the chip, having a front face and a rear face opposite the front face, includes a device at one of the front and rear faces and a plurality of bond pads exposed at one of the front and rear faces. The device is operable as a transducer of acoustic energy. The package element includes a dielectric element and a metal layer disposed on the dielectric element. The metal layer includes a plurality of contacts conductively connected to the bond pads. In this embodiment, the package element includes a recess in registration with the device, the chip and the recess forming a closed cavity adjacent to the device.

Preferably, the package element includes an inner surface facing the chip, an outer surface facing away from the chip, a plurality of inner via terminals disposed at the inner surface. Such package elements also includes a plurality of outer via terminals disposed at the outer surface, and vias interconnecting the inner via terminals and the outer via terminals. In such preferred embodiment, the metal layer may further include traces extending between the contacts and the inner via terminals. Preferably, the packaged chip further includes wire bonds which conductively connect the bond pads to the contacts. Preferably, the dielectric element in such package element consists essentially of a ceramic material and/or may include a laminate structure.

According to another aspect of the invention, a packaged chip is provided which includes a chip and a package element. The chip, having a front face and a rear face opposite the front face, includes a device at one of the front and rear faces, the device being operable as a transducer of acoustic energy. The chip also includes a plurality of bond pads exposed at one of the front and rear faces.

In this aspect of the invention, the package element includes a through hole. Like the aforementioned package elements, the package element of this embodiment includes a dielectric element and a metal layer having a plurality of contacts disposed on the dielectric element. The package element includes a recess aligned to the through hole. A lid is provided which covers the recess, and one of the front and rear faces of the chip is mounted to the package element within the recess such that the chip is aligned to the through hole to permit passage of acoustic energy to and from the device and a space beyond the package element. Further, the recess and the lid form an enclosed cavity adjacent to a different one of the front face and the rear face of the chip.

According to yet another aspect of the invention, a packaged chip is provided in which a chip includes an acoustic transducer and has a plurality of bond pads. A package element is included in the packaged chip which includes a dielectric element and a metal layer disposed on the dielectric element. The metal layer has a first surface contacting the dielectric element, and a second surface facing away from the dielectric element. The metal layer includes a plurality of chip contacts exposed at one of the first and second surfaces, the chip contacts being conductively connected to the bond pads. The package element further includes a plurality of interconnects conductively connected to the chip contacts. The interconnects are exposed at one of the first and second surfaces. The package element further includes a first opening aligned to the acoustic transducer for passage of acoustic energy to and from the acoustic transducer. According to this aspect of the invention, an interconnection element is further provided which has a top surface, a bottom surface opposite the top surface, and a recess disposed between the top surface and the bottom surface. A plurality of top contacts are exposed at the top surface of the interconnection element. A plurality of bottom contacts exposed at the bottom surface, and conductive features interconnect the top contacts to the bottom contacts. The top contacts are conductively bonded to the interconnects of the package element.

Preferably, in such embodiment, the interconnection element includes a stack of dielectric layers, wherein the conductive features include conductive elements that are disposed in the dielectric layers. Preferably, such dielectric layers consist essentially of a ceramic material and/or reinforced fiberglass.

Preferably, an assembly including a packaged chip according to such embodiment further includes outer contacts exposed at the one of the first and second surfaces on a side of the package element opposite the chip contacts. A circuit panel of the assembly has terminals conductively mounted to the outer contacts. The circuit panel further includes an opening aligned to the opening in the package element to permit passage of the acoustic energy to or from the acoustic transducer through the circuit panel.

According to another preferred aspect of the invention, an assembly is provided in which a circuit panel has terminals conductively mounted to the bottom contacts of the interconnection element, such that the first opening of the package element faces away from the circuit panel to permit passage of the acoustic energy to or from the acoustic transducer through the first opening.

According to yet another preferred aspect of the invention, in such assembly, the bottom contacts of the circuit panel are preferably mounted to the interconnection element by at least one of a fusible conductive material, conductive stud bumps, and an anisotropic conductive film.

According to another aspect of the invention, a packaged chip is provided in which a chip, having a front face and a rear face opposite the front face, includes a device at one of the front and rear faces and a plurality of bond pads exposed at one of the front and rear faces. The device is operable as a transducer of at least one of acoustic energy and electromagnetic energy. Such packaged chip includes a package element having a dielectric element and a metal layer disposed on the dielectric element. The package element has an inner surface facing the chip and an outer surface facing away from the chip. The metal layer of the package element includes a plurality of contacts exposed at at least one of the inner and outer surfaces, the contacts being conductively connected to the bond pads. In such embodiment, the package element is spaced from the chip so as to define a cavity between the transducer and the package element.

In a particular embodiment, the cavity is closed.

An assembly including a packaged chip according to this aspect of the invention further includes a circuit panel having terminals conductively mounted to the contacts of the package element.

According to yet another aspect of the invention, a method of making a packaged chip is provided. According to such aspect, a chip is provided which has a front face and a rear face, the chip including a device disposed at at least one of the front face and the rear face and a plurality of bond pads exposed at one of the front face and the rear face. The device is operable as a transducer of at least one of acoustic energy and electromagnetic energy.

According to this aspect of the invention, a package element is provided which includes a dielectric element and a metal layer having a plurality of contacts. The package element further includes a first opening. The chip is mounted to the package element such that the first opening is aligned to the device and the bond pads of the chip are then bonded to the contacts.

Preferably according to such aspect of the invention, the device includes an image transducer. Preferably, the method further includes aligning a photo-scintillator element to the first opening, and mounting the aligned photo-scintillator element to the package element.

In one preferred embodiment, the photo-scintillator element further includes a carrier layer which is mounted to the package element.

In a particular preferred embodiment, the package element have an inner surface facing the front face of the chip and the photo-scintillator element be mounted to the inner surface.

### BRIEF DESCRIPTION OF THE DRAWINGS

FIG. 1 is a sectional view illustrating a gull-wing style surface mountable packaged chip according to the prior art.

FIGS. 2-3 are sectional views illustrating packaged acoustic transducer chips according to the prior art.

FIG. 4 illustrates a unit element of a packaged acoustic transducer chip, according to an embodiment of the invention.

FIGS. 5A and 5B illustrate variations of a packaged chip according to one embodiment of the invention.

FIGS. 6A-6B illustrate variations of a packaged chip according to another embodiment of the invention.

FIG. 6C illustrates an assembly including a packaged chip according to an embodiment illustrated in FIG. 6A or 6B.

FIGS. 7A, 7B and 8A are sectional views illustrating embodiments of the invention which include fold packages.

FIG. 7C is a sectional view illustrating a unit element of a packaged acoustic transducer chip, according to another embodiment of the invention.

FIG. 8B is a plan view illustrating a pattern of conductive traces and contacts in a package element, in the fold package embodiment of the invention illustrated in FIG. 8A.

FIG. 9 is a sectional view illustrating a packaged acoustic transducer chip including a cap element, according to one embodiment of the invention.

FIG. 10 is a sectional view illustrating an assembly of the packaged chip shown in FIG. 9 together with a circuit panel, according to an embodiment of the invention.

FIG. 11 is a sectional view illustrating a further embodiment of the invention, in which a package element is sealed to an underlying circuit panel to form a cavity adjacent to one face of the acoustic transducer chip.

FIGS. 12A-12C are sectional views illustrating embodiments of the invention in which conductive interconnects extend from bond pads of the chip through a set of through holes in a lid overlying the chip.

FIGS. 13A and 13B are sectional views illustrating embodiments of the invention in which unit elements include an acoustic transducer chip and a back plate disposed behind a rear surface of the chip.

FIG. 14 is a sectional view illustrating another embodiment of the invention in which a cavity is disposed between the front surface of the chip and a lid and an acoustic port is disposed behind the rear surface of the chip.

FIG. 15 is a sectional view illustrating an assembly including a packaged chip illustrated in FIG. 14 as mounted to a circuit panel.

FIG. 16 is a sectional view illustrating an embodiment in which an acoustic transducer is mounted within a gull-wing style package having a cavity and an acoustic port.

FIG. 17 is a sectional view illustrating yet another embodiment in which an acoustic transducer is mounted within a unit which is surface-mountable by way of solder bumps disposed along a lower edge, the unit having a cavity and an acoustic port.

FIG. 18 is a sectional view illustrating details of an interconnection arrangement within the unit illustrated in FIG. 17.

FIG. 19 is a sectional view illustrating a packaged chip according to yet another embodiment in which an acoustic transducer is mounted within a unit which is surface-mountable through contacts disposed at an upper edge and at a lower edge.

FIG. 20 is sectional view illustrating a packaged chip according to another embodiment in which an acoustic transducer is mounted within a unit which is surface-mountable from a lower edge.

FIG. 21 is a sectional view illustrating an alternative interconnection arrangement between elements of a packaged chip, in an embodiment similar to that shown in FIG. 20.

FIG. 22 is a plan view illustrating a package element or chip carrier utilized in an embodiment of the invention including a transducer of electromagnetic energy.

FIGS. 23-26 illustrate stages in fabrication of a packaged chip and assembling of the packaged chip to a circuit panel, according to an embodiment of the invention.

FIGS. 27-31 illustrate packaged chips including electromagnetic energy transducing chips according to various other embodiments of the invention.

### DETAILED DESCRIPTION

Microelectronic elements such as semiconductor chips or “dies” are commonly provided in packages which protect the die or other element from physical damage, and which facilitate mounting of the die on a circuit panel or other element. One type of microelectronic package includes a substrate, also referred to as a “tape” incorporating a dielectric layer such as a layer of a polyimide, BT resin or other polymeric material with electrically conductive features such as contacts on the dielectric element. The die is mounted on the substrate so that a face of the die confronts the substrate, typically with a layer of a die attach adhesive between the die and the substrate. The contacts or “terminals” are exposed at an outer surface of the substrate, but are electrically connected to contacts on the die itself. A protective material commonly referred to as an overmolding may surround the die itself, but desirably does not cover the terminals. Such a package can be mounted on a circuit board with the outer surface of the substrate facing toward the circuit board, and with the terminals aligned with contact pads on the circuit board. Conductive bonding materials such as solder balls can be used to bond the terminals to the contact pads, so as to physically mount the package in place on the board and connect the terminals to the circuitry of the board, thereby connecting the die to the circuitry. When the package is mounted to the circuit board, the substrate lies beneath the die, between the die and the circuit board.

As disclosed, for example, in commonly assigned U.S. patent application Ser. Nos. 10/281,550, filed Oct. 28, 2002; Ser. No. 10/077,388, filed Feb. 15, 2002; Ser. No. 10/654,375, filed Sep. 3, 2003; Ser. No. 10/655,952, filed Sep. 5, 2003; Ser. No. 10/640,177, filed Aug. 13, 2003; Ser. No. 10/656,534, filed Sep. 5, 2003; Ser. No. 10/448,515, filed May 30, 2003; U.S. Provisional Patent Application Ser. No. 60/515,313, filed Oct. 29, 2003, in commonly assigned PCT International Application Nos. PCT/US03/25256, filed Aug. 13, 2003; PCT/US03/27953, filed Sep. 5, 2003; and PCT/US03/28041, filed Sep. 8, 2003, and in U.S. Pat. Nos. 6,121,676 and 6,699,730, the disclosures of all of the foregoing issued patents and pending applications being incorporated by reference herein, a package referred to herein as a “fold” package incorporates a generally similar substrate or tape. However, the substrate or tape in a fold package is folded so as to define a pair of superposed runs extending in generally parallel planes. One such run extends below the die, in the position occupied by the substrate of the conventional package, whereas the other run extends above the die, with the die disposed between the runs. The bottom run typically bears terminals used to mount the package to a circuit panel or other larger substrate. In some variants of the fold package, electrically conductive components on the top run include terminals exposed at the outer surface (the surface facing upwardly away from the die and away from the bottom run), so that other packaged or unpackaged microelectronic elements can be mounted on the top run of the fold package. Fold packages of this type can be stacked, one on top of the other. The features on the top run are interconnected with the terminals or other electrically-conductive features on the bottom run by traces extending along the dielectric element. These traces extend around the fold formed in the dielectric element. In some embodiments, the contacts on the die disposed between the runs are connected to bond pads on the top run, and the traces connect these bond pads to terminals on the bottom run.

In a further variant, two or more microelectronic elements such as two or more semiconductor dies are mounted in the space between the top and bottom runs.

Still other fold packages combine these approaches, so that two or more microelectronic elements are disposed in the space between the top and bottom runs of the package, and the package has exposed terminals on both the top run and the bottom run, and hence can be stacked or otherwise combined with additional packages of the same or different types and/or with additional microelectronic elements.

Fold packages provide certain significant advantages. The traces which extend between the top and bottom runs can be formed in the normal tape-fabrication process at little additional cost, so as to provide low-cost, reliable interconnections between the two runs. The folded substrate substantially surrounds the die or other elements between the runs, and thus provides additional physical protection to these elements. Also, the substrate can include electrically conductive elements which provide electromagnetic shielding around the die or other elements disposed between the runs.

In a particular embodiment herein, a micro-electromechanical device incorporated in a die may be mounted in a fold package. Where the device includes a microphone or other transducer, the fold package may be provided with an opening in one run of the substrate for admitting sound waves or other phenomena to be detected or measured by the transducer. The fold package may additionally define an acoustic cavity for use in conjunction with a microphone.

According to one of the embodiments of the invention, a packaged acoustic chip is provided which includes an opening, i.e., an “acoustic port” for the passage of acoustic energy, e.g., a pressure wave, and which also includes an air- or other fluid-filled cavity, as required for the acoustic transducer to function. As mentioned above, acoustic transducers are just one type of MEMS chips: other MEMS chips can be packaged according to the embodiments described herein. FIG. 4 is a diagram illustrating a stage in the fabrication of a packaged acoustic transducer chip 80 such as a MEMS microphone. As illustrated therein, an acoustic transducer 81 is provided on a chip 78, as a parallel plate capacitor having a fixed plate 82 and a movable plate 83 which moves in accordance with a pressure wave that impinges thereon. The transducer 81 can be mounted such that the pressure wave impinges on the movable plate either from above the front face 84 of a chip 78 which contains the transducer, or from below the rear face 86 of the chip 78. The chip can be provided from one of a variety of semiconductor materials such as silicon, and alloys of silicon (e.g., silicon germanium), as well as III-V or II-VI compound semiconductors. The movable plate is provided, for example, by locally thinning a region of the silicon chip. The fixed plate is preferably provided as a rigid region of the silicon chip, having an array of through holes which permit the passage of a gas, e.g., air, between a cavity region below the rear surface 86 of the chip and the movable plate 83 of the capacitor.

The acoustic transducer 81 is electrically interconnected to electronic circuitry 89 on the chip 78, which, in turn is connected to bond pads 88. Alternatively, or in addition thereto, the transducer 81 is directly electrically interconnected to bond pads 88 by way of conductive wiring traces 90. As shown in FIG. 4, the conductive wiring traces are preferably formed to at least partially overlie the bond pads 88, in a manner such as that described in commonly owned U.S. patent application Ser. No. 10/977,515, filed Oct. 29, 2004, which application claims the benefit of the filing dates of U.S. Provisional Patent Application Nos. 60/515,615 filed Oct. 29, 2003 and 60/532,341 filed Dec. 23, 2003. Said application and provisional applications are hereby incorporated by reference herein. In turn, the bond pads 88 of the chip are joined by a conductive bonding material to corresponding inner contacts 92 of a package element 95. The package element 95 includes a dielectric element 94 and conductive traces 96 disposed thereon, and includes an opening 100 overlying the front surface 84 of the acoustic transducer chip. The dielectric element 94 is preferably implemented by a layer of polymeric material such as polyimide commonly referred to as a “tape”, on which a metal layer is patterned, such as a copper layer or stack of metal layers, to form the traces 96. The tape is such as commonly used for tape automated bonding (TAB), and in the production of packaged μBGA® chips (registered trademark of Tessera, Inc.). The dielectric element 94 preferably includes openings 98 through which a plurality of outer contacts 99 are exposed for joining the assembly 80 to a circuit panel, for example. The outer contacts 99 are connected to the inner contacts 92 by way of the traces 96.

As particularly shown in FIG. 4, the bond pads 88 of the chip are bonded to the contacts 92 of the package element by way of solder balls. However, other interconnection arrangements can be provided such as one in which a conductive adhesive, especially an anisotropic conductive adhesive, is used to bond the chip to the conductive traces 96 of the package element 95.

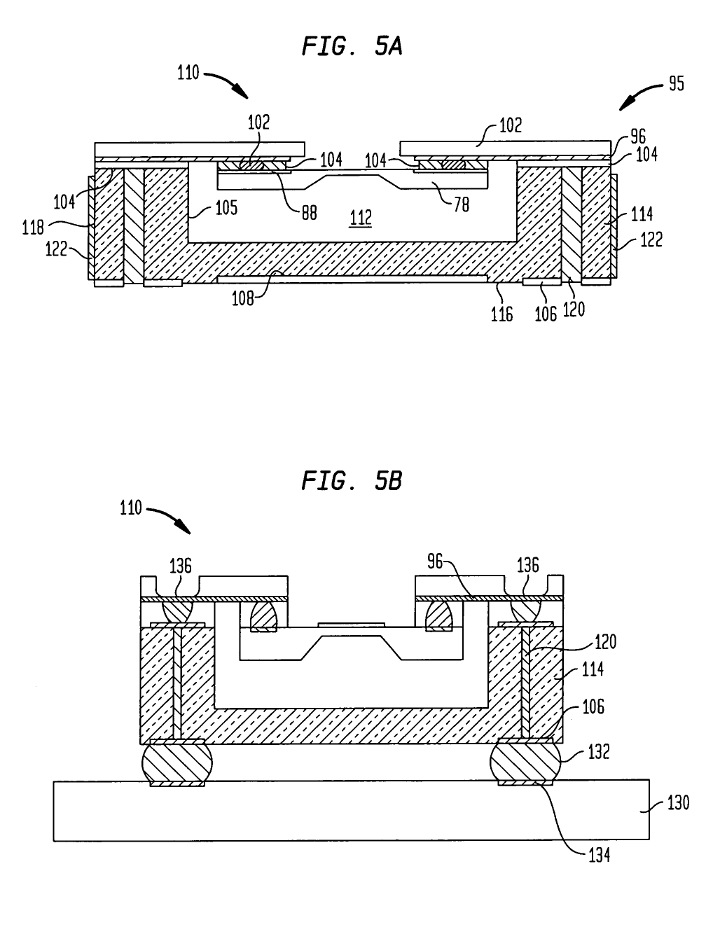

Alternatively, stud bumping in connection with adhesive or solder bonding can be utilized to form the interconnections. An example of such structure is illustrated in FIG. 5A, in which conductive stud bumps 102, are preferably provided of a noble metal such as gold, silver, copper, or platinum for corrosion resistance, and are most preferably provided of gold for malleability. The stud bumps 102 are preferably formed on the bond pads 88 of the chip, and an anisotropic conductive film (ACF) 104 is provided to overlie the metal layer 96 where that layer is joined to the bond pads 88 of the chip 78.

In yet another variation, the package element can contain leads (not shown) formed integrally to the metal layer, the leads being deformed and bonded to bond pads of the chip.

FIG. 5A illustrates a completed structure in which the packaged chip 110 includes a cavity 112 which is enclosed by a housing 114 having a bottom side 116 and sidewalls 118. The housing 114 can be provided of one or more essentially dielectric materials such as ceramics, polymers, glasses, or combination of the same, or, alternatively, one or more semiconductor materials or metals. The housing 114 can have a laminate structure, such as one provided of a stack of dielectric layers, such as layers of FR-4 type epoxy reinforced fiberglass material. As shown in FIG. 5A, conductive vias 120 are provided which extend through the housing 114 to conductively interconnect the traces 96 to contacts 106 located on the bottom side 116. A conductive plane 108 is preferably also provided on the bottom side 116 of the housing, for use in providing shielding against spurious electromagnetic emissions generated by the acoustic transducer 82. Sidewall conductive planes 122 are also desirably provided on sidewalls of the housing, such planes being provided either externally, as shown in FIG. 5A, or internally instead on inside walls 105 of the housing. When the metal layer from which the traces 96 is patterned remains substantially intact as a metallic sheet, the metal layer, together with the conductive plane 108 and sidewall conductive planes 122, functions as a Faraday cage to substantially reduce the amount of unwanted electromagnetic emissions from the chip 78.

FIG. 5B illustrates further interconnection of the packaged chip 110 to a circuit board 130 by way of solder balls 132 which provide conductive interconnection between contacts 106 on the bottom side of the housing 114 and terminals 134 provided on the circuit board. As further shown in FIG. 5B, an additional set of contacts 136 can be provided which are exposed at the top surface of the packaged chip 110, the contacts 136 connecting to the traces 96 of the packaged chip for interconnection to both the chip and the vias 120 of the housing, as described above with respect to FIG. 5A.

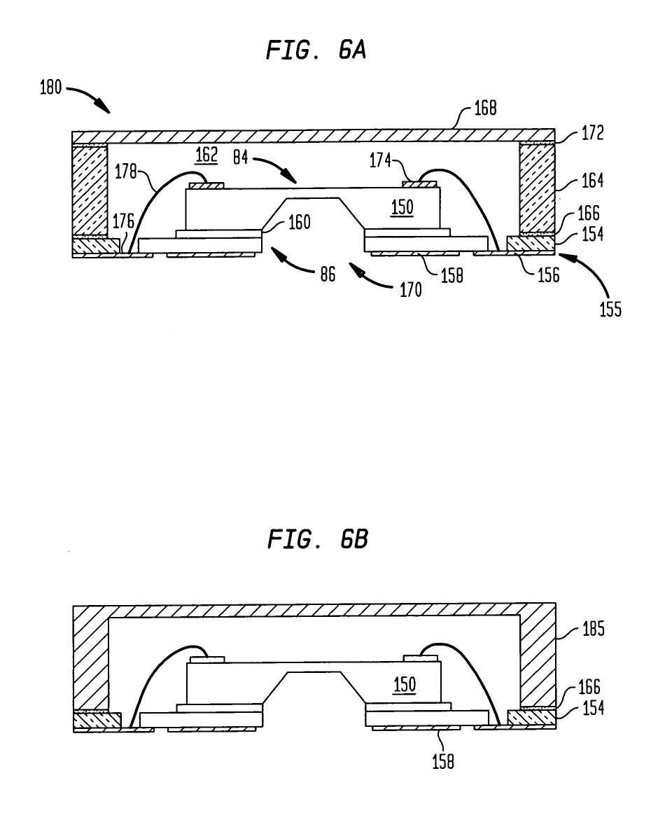

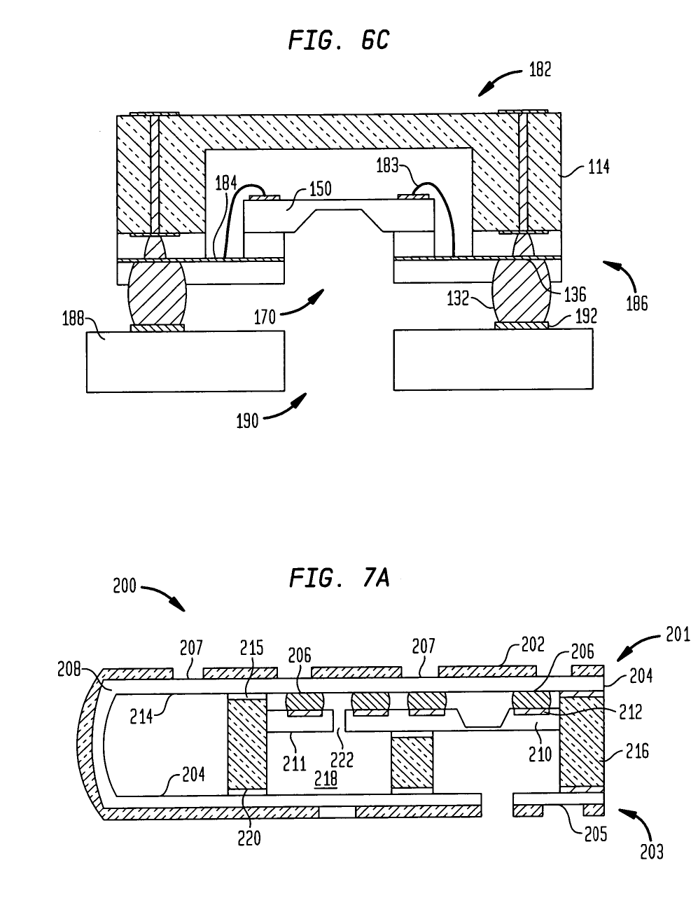

FIG. 6A illustrates an alternative embodiment of a packaged chip 180 in which a chip 150 is mounted with the front face 84 of the chip facing away from the package element 155 to which it is conductively connected. In such embodiment, the rear face 86 of the chip 150 is mounted to a package element 155 by a die attach material 160. In this embodiment, the cavity 162 is disposed adjacent to the front face 84 of the chip to which the movable plate of the transducer is closest. The fixed plate of the acoustic transducer is disposed adjacent to an opening 170 in a package element 155. As in the above-described embodiment, the package element 155 includes a dielectric element 154 and a metal layer including traces 156 for providing interconnectivity, as well as for providing shielding. The bond pads 174 of the chip are conductively interconnected to inner contacts 176 of the package element 155 by way of wire bonds 178.

As further shown in FIG. 6A, the chip 150 is enclosed within a housing 164 that is mounted, for example, as by an adhesive 166 to the dielectric element 154 of the package element. Desirably, the housing 164 is molded into final form prior to placement on and bonding to the package element 155, such as can be provided by molding a polymer according to any of many well-known techniques. A lid 168, which preferably consists essentially of a metal, is bonded to the housing 164 by way of an adhesive 172 to overlie the chip 150. In such way, the metallic lid 168 disposed at a top surface of the package and the conductive plane 158 disposed at the bottom surface of the package provide electromagnetic shielding from emissions of the acoustic transducer chip.

FIG. 6B illustrates a variation of the embodiment illustrated in FIG. 6A. This embodiment varies from that shown in FIG. 6A in that a metal can 185 is used in place of a plastic housing combined with a metal lid. The metal can is mounted, for example, by an adhesive 166, to the dielectric element 154. In this case, the metal can 185 surrounds the chip 150 on all but one side, and the conductive plane 158 covers the remaining side of the chip 150 such that an even greater degree of electromagnetic shielding results than that provided in the embodiment shown in FIG. 6A.

FIG. 6C further illustrates interconnection of a packaged chip 182, having a housing 114 similar to that shown in FIG. 5A, but in which the chip 150 is conductively connected by wire bonds 183 to inner contacts 184 of the package element 186. The packaged chip 182 is mounted to a circuit board 188 in a position with the acoustic port 170 facing the circuit board, the circuit board having a through hole 190 permitting acoustic energy to pass to and/or from the chip 150. Conductive interconnection of the packaged chip 182 to the circuit board 188 is provided through interconnects, e.g., solder balls 132, connecting the external contacts 136 on the top (chip-facing) side of the packaged chip to terminals 192 provided on the circuit board.

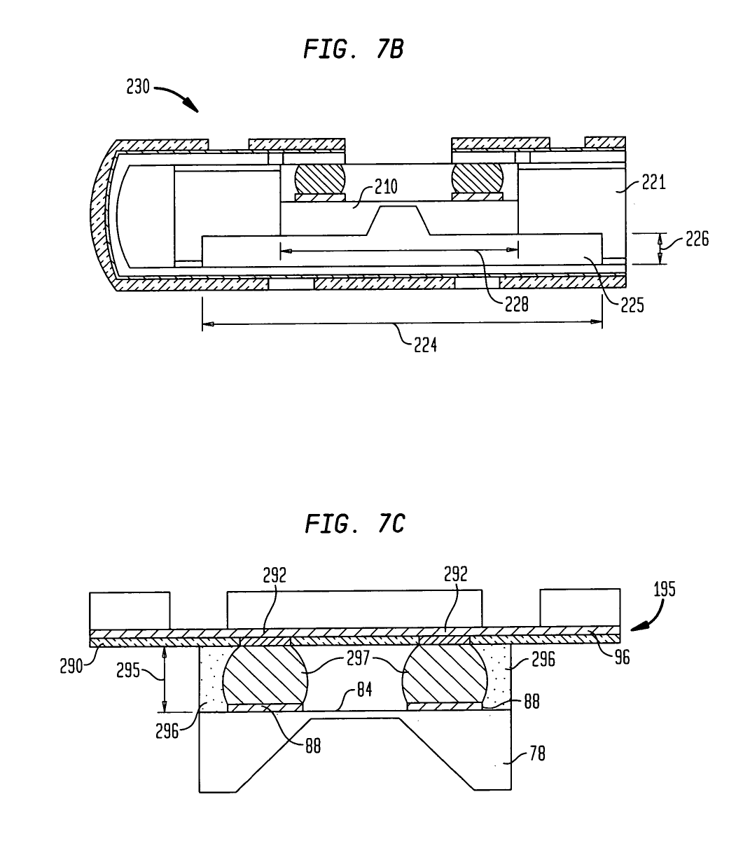

FIG. 7A illustrates a packaged chip having a fold package structure according to another embodiment of the invention. Fold packages have been utilized to create vertically stacked semiconductor chips, such as for the purpose of achieving a greater degree of functionality for a given area of a substrate. Fold packages are disclosed in U.S. Pat. Nos. 6,121,676 and 6,225,688, for example, the disclosures of which are hereby incorporated by reference herein.

Similar to some of the embodiments of the invention described above with reference to FIGS. 4-6B, a fold package is fashioned from a flexible dielectric element or tape 202 on which a patterned metal layer 204 is disposed. The patterned metal layer contains features such as contacts 206 and traces 208 which facilitate interconnection between the chip and items, e.g., circuit panels external to the chip through external contacts 207 disposed on a top portion 201 of the tape and external contacts 205 disposed on the bottom portion 203 of the tape.

The fold package structure is intrinsically compliant, such that the chip is buffered against stresses arising from thermal expansion between the tape and the chip. As used herein, “compliant” means ready, disposed, or likely to yield to an applied stress, and a “compliant layer” refers to a layer of material that has a compliant property. There are numerous ways to make a compliant layer. One simple way is to use a continuous layer of material that is sufficiently thick that it yields in response to stresses caused by differential thermal expansion. Typically, the degree of compliancy increases with the thickness of the compliant layer. However, a compliant layer can be made relatively thin by use of a material that is itself fairly compliant, such as an elastomer, a B-stageable material, a thermoplastic or other polymer, a low modulus epoxy, or a “low stress” die attach material that softens significantly as the package is heated to its maximum operating temperature. The elastic modulus of a material gives some indication of its compliancy; the lower the modulus, the more compliant the material is. However, in some cases, a layer made from a material having a higher modulus of elasticity can often be made as compliant as a layer made from a material having a lower modulus, for example, by using a thicker layer of the higher modulus material or by making holes in the material. However, packages having compliant layers are sometimes less resistant to warping. In a fold package, warping need not be fully eliminated to achieve a package having a level of compliancy which compensates for thermal expansion mismatch, such that the manufacturability of the package and its reliability at the level of the circuit board are significantly improved.

FIG. 7A illustrates an embodiment of a packaged chip 200 in which a chip 210 is bonded by a fusible conductive material such as a solder disposed between bond pads 212 of the chip and the contacts 206 of the patterned metal layer. A top surface 215 of a ring frame structure 216, similar to the housing 164 described above with reference to FIG. 6A, is bonded to an inner side 214 of the metal layer 204 at the top portion 201 of the tape 202. The ring frame structure 216 is desirably formed of a molded polymer. The tape 202 is folded 180 degrees to extend around the ring frame structure, such that the patterned metal layer 204 at the bottom portion 203 of the tape is bonded to a bottom surface 220 of the ring frame structure. This results in the chip 210 being substantially enclosed by the ring frame structure 216 and the tape 202. In the embodiment shown in FIG. 7A, either the dielectric layer or the ring frame structure, or both can be provided of a compliant layer. However, because of the larger height of the ring frame structure 216, it is desired that the ring frame structure have a degree of compliancy per unit thickness which is less than the dielectric layer 202 of the tape.

As further shown in FIG. 7A, the molded ring frame is partitioned to enclose a second space 218 between the front face 211 of the chip 210 and the top and bottom portions 201, 203 of the tape 202. The second space 218 can be utilized as the acoustic cavity required for operation of the acoustic transducer within the package 200. As also shown in FIG. 7A, the chip 210 further includes a port 222 for permitting the passage of a fluid, e.g., a gas such as air, or liquid, for the purpose of stably maintaining a pressure at a fixed plate of a movable plate of the capacitor-type transducer.

FIG. 7B illustrates a variation of the embodiment shown in FIG. 7A, in which the ring frame 221 of a unit 230 including an acoustic transducer chip is constructed in such way that it encloses a volume having a lateral dimension 224 that is larger than a lateral dimension 228 of the back face of the chip. In such way, a large volume cavity 225 is enclosed by the ring frame 221 that has low height 226, such that the unit 230 has a low profile. Thus, the fold package of unit 230 provides a means by which the height of the unit 230 can be reduced by expanding the lateral dimension 224, and hence, the area that the cavity occupies.

FIG. 7C illustrates a further embodiment of a chip 78 as mounted to a modified package element 195 which does not have an opening in the metal layer, such that a closed cavity is formed adjacent to the device-bearing surface 84 when the package element is joined to the chip. In such embodiment, the device-bearing surface 84 of the chip is desirably maintained at a substantial spacing 295 from the major surface of the package element 195 defined by the metal layer 96. The spacing 295 can be determined at least partly by the size of conductive interconnection elements such as large solder balls 297 which conductively connect the bond pads 88 of the chip to contacts 292 of the package element 195. A solder mask 290 or other dielectric material prevents the solder from solder balls 297 from spreading beyond the contacts 292. A sealing medium 296 preferably surrounds the interconnection elements 297 in a “picture frame ring seal” arrangement, so as to seal the cavity from the exchange of a gas or other fluid, and to protect the device on the front surface 84 of the chip from damage or other degradation due to contamination. The chip can be mounted to the package element and be electrically interconnected thereto in a variety of ways. For example, the chip can be mounted by way of conductive stud bumps which extend from either the bond pads of the chip or from the contacts of the package element. In such case, the stud bumps can be joined to the other of the bond pads and the contacts through conductive features such as masses of fusible material or an anisotropic conductive adhesive, for example, which is used to complete the conductive interconnects. Other means of forming conductive interconnects include use of deformable leads, as will be described below with reference to FIG. 21.

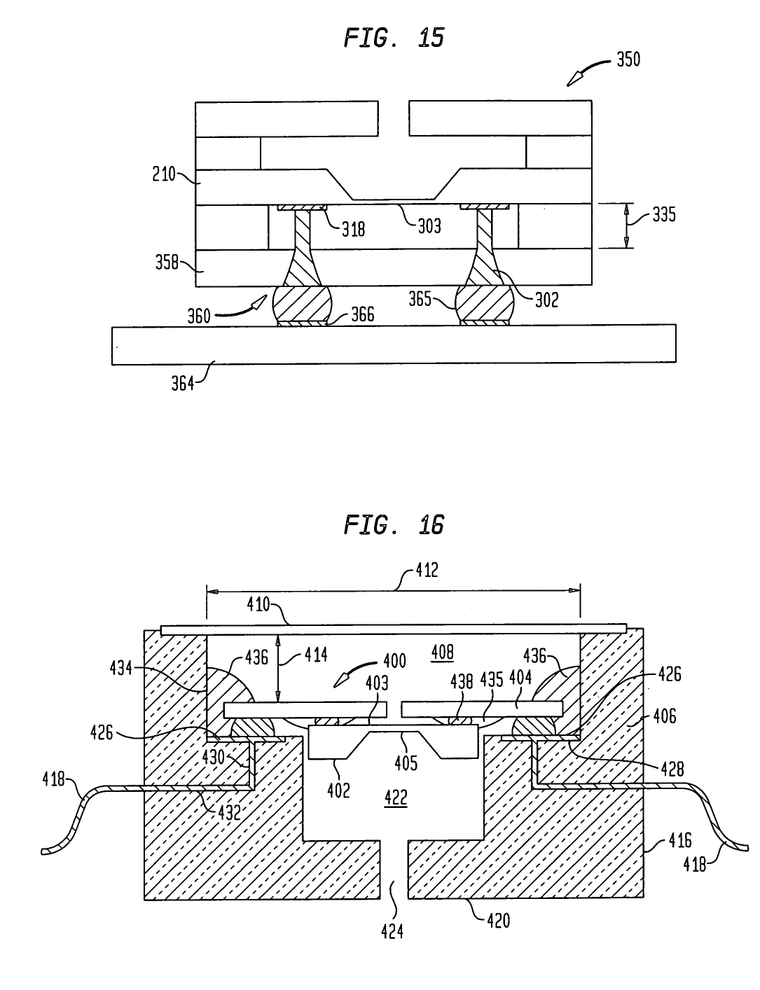

Other embodiments which include a chip 78 mounted to a package element to enclose a cavity adjacent to a device of the chip are shown in FIGS. 7A, 7B, 8A, 10, 11, 13A, 13B, 14, 15, and 19 and 20 herein, among others, these being as described above, and as will be further described below. In addition, the chip 78 can be mounted to a circuit panel in a variety of arrangements, such as those shown and described above with respect to FIGS. 15-19.

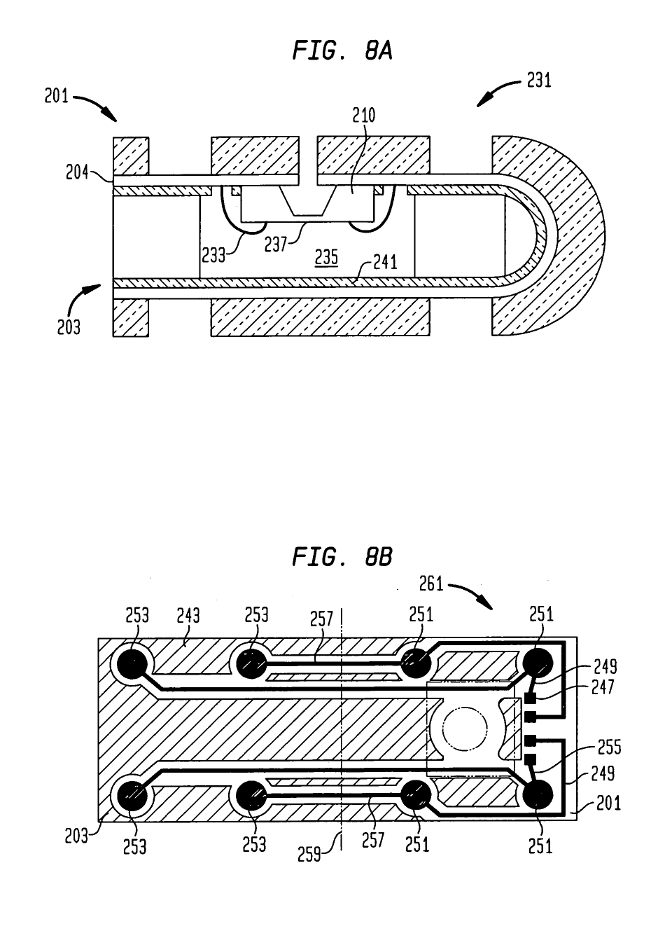

FIGS. 8A and 8B illustrate yet another fold package embodiment of a unit 231 in which a chip is conductively interconnected to the metal layer 204 of a tape by wire-bonds 233. The chip 210 is mounted therein such that the acoustic cavity 235 is disposed between the front or contact-bearing surface 237 of the chip 210 and a bottom portion 203 of the tape 201. Additionally, a solder mask 241 or additional dielectric layer can be provided on an inner surface of the metal layer 204, if desired to further isolate electrical traces which run within the metal layer 204.

FIG. 8B is a plan view illustrating a particular embodiment showing the metal layer 243 of a package element 261 which forms a part of the packaged chip unit 231 shown in FIG. 8A. Inner contacts 247 of the metal layer connect to traces 249 which are conductively connected to a first set of external contacts 251 which are provided on a first, e.g., top portion 201 of the tape. However, additional traces 257 conductively connect the first external contacts 251 past fold line 259 to second external contacts 253 which are provided on a second, e.g., bottom portion 203 of the tape. Such structure permits the packaged chip 231 to be conductively interconnected and assembled to a circuit board in a higher-level assembly through either the first contacts 251 or the second contacts 253. As further shown in FIG. 8B, the metal layer 243 is patterned to remain a unitary sheet of metal to the maximum extent amount possible to provide electromagnetic shielding, the metal sheet desirably surrounding many of the traces 249, 257 and contacts 251, 253 on the package element 261.

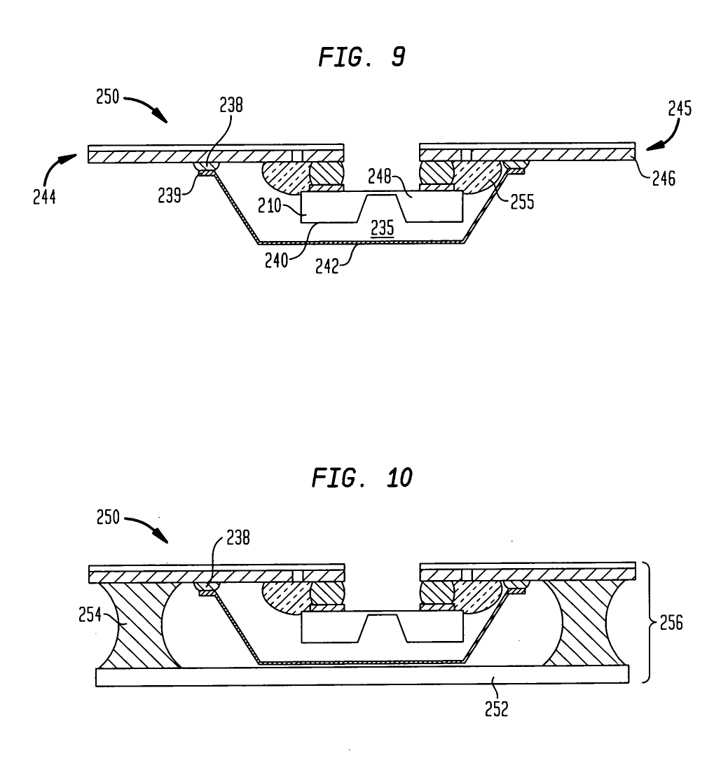

FIG. 9 is a sectional view illustrating a unit 250 including an acoustic transducer chip 210 which is mounted to a circuit panel, e.g., a flexible tape 244, according to another embodiment of the invention. As shown therein, the cavity 235 required for the acoustic transducer to operate is disposed between the bottom face 240 of the chip 210 and a cap 242, the cap being desirably formed of a metal. As shown in FIG. 9, the cap 242 is bonded to the metal layer 246 of a circuit panel, e.g., flexible, rigid or semi-rigid (compliant) circuit panel 245 to which the acoustic transducer chip is bonded, such as for the conduction of electrical signals to and from the chip 210. Preferably, the cap 242 is bonded to the metal layer 246 through a mass 238 of adhesive or fusible material such as solder which extends around the periphery of the cap 242. A sealing material 255 is provided at the opening in the circuit panel 245 to seal the front face 248 of the chip 210 to the circuit panel 245, preferably an organic material such as a polymer, in order to establish a sealed cavity 235 between the chip 210 and the cap 242.

FIG. 10 illustrates a higher order assembly 256 which is constructed by bonding the unit 250 to a circuit board 252, such as one commonly known as an FR-4 type or BT resin type board, using a fusible material such as solder to form conductive interconnects 254 between the unit 250 and the circuit panel 252. Owing to its low height which is not greater than the height of the soldered conductive interconnects, the unit 250 can be assembled to the circuit board 252 to form a low-profile product. In such case, the solder connection are effectively recessed within the package height, and, therefore, do not contribute to the overall height of the assembly 256.

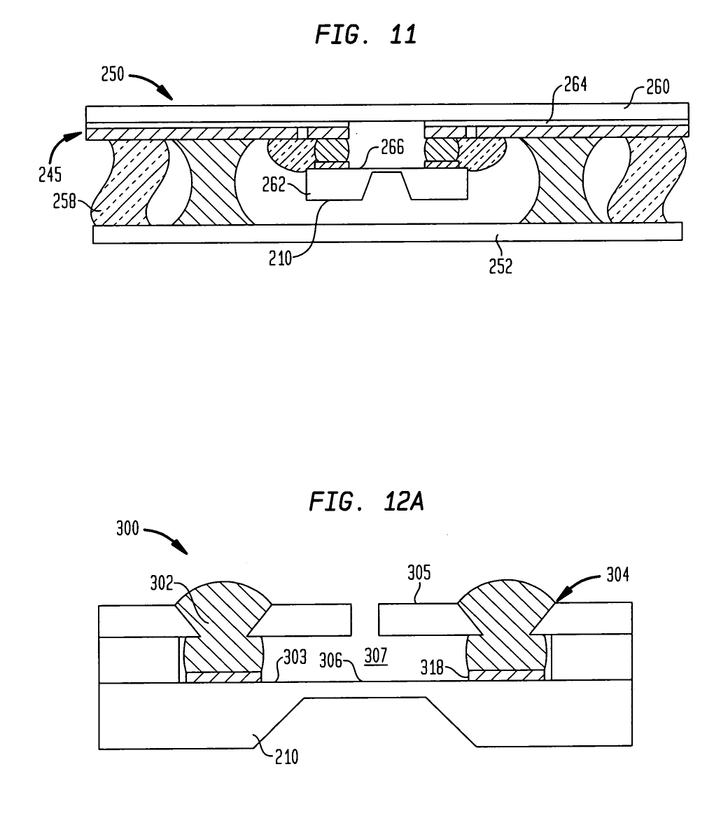

FIG. 11 shows a variation of the embodiment of the invention shown in FIG. 9. As depicted therein, a unit 250 such as that shown and described above relative to FIG. 9, rather than being joined to a cap for enclosing the required cavity, is instead sealed to the circuit board 252 by way of a perimeter seal 258. Viewed from above, the seal encloses the chip 210 on the four (or more) peripheral edges 262 of the chip. The seal 258 is preferably provided as an organic sealing material which is disposed between the package element or tape 245 and the circuit board 252. However, other sealing materials can be used, including low melting point glasses, fusible materials such as solder, thermoplastics, adhesives, and other polymers.

Another variation of the embodiment shown in FIG. 11 is the provision of a sacrificial or disposable layer 260 over an external surface 264 of the package element 245. The disposable layer 260 is desirably disposed on the surface 264 of the package element 245 during steps in which the chip 210 is mounted to the package element 245 to form the unit 250, and those in which the unit is joined to the circuit board 252. The disposable layer serves a function of protecting the exposed surface 266 of the acoustic transducer chip 210 from ingress of foreign material or other contamination during these processing steps. The disposable layer may include a flexible material which can be peelably removed from the unit 250. Alternatively, the disposable layer includes a less flexible member, or rigid member which can be easily detached and cleanly removed from the package element 245. The disposable layer may even be allowed to remain disposed on the surface of the package element 245 during still other stages of manufacturing, until the unit 250 assembled into electronic equipment containing a microphone and then sold in that condition to a customer. The customer or end user upon using the electronic equipment can then peelably remove or otherwise lift off the disposable layer 260 from the unit 250 for use of the equipment.

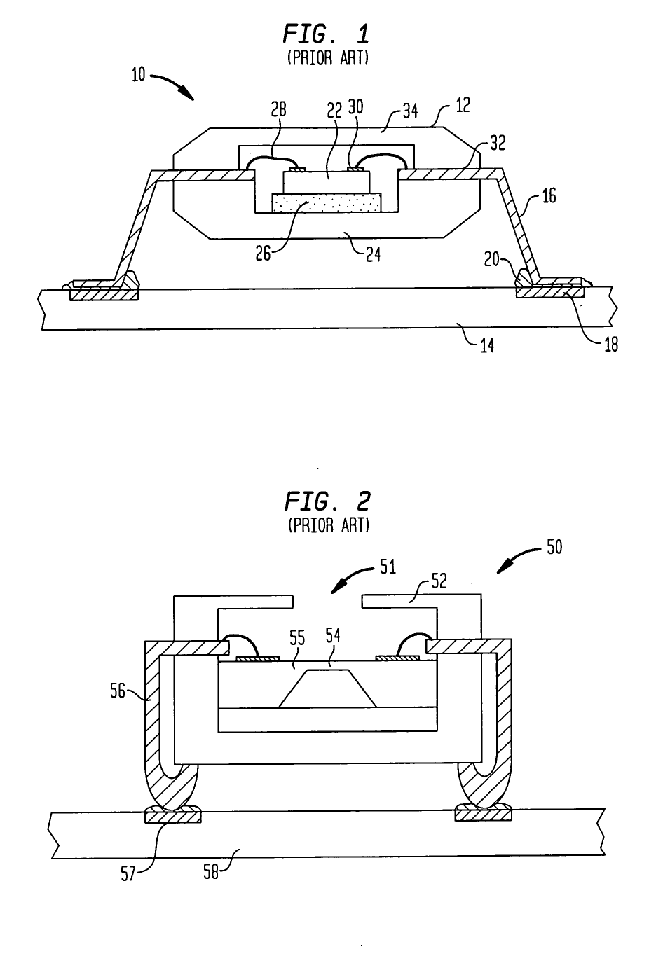

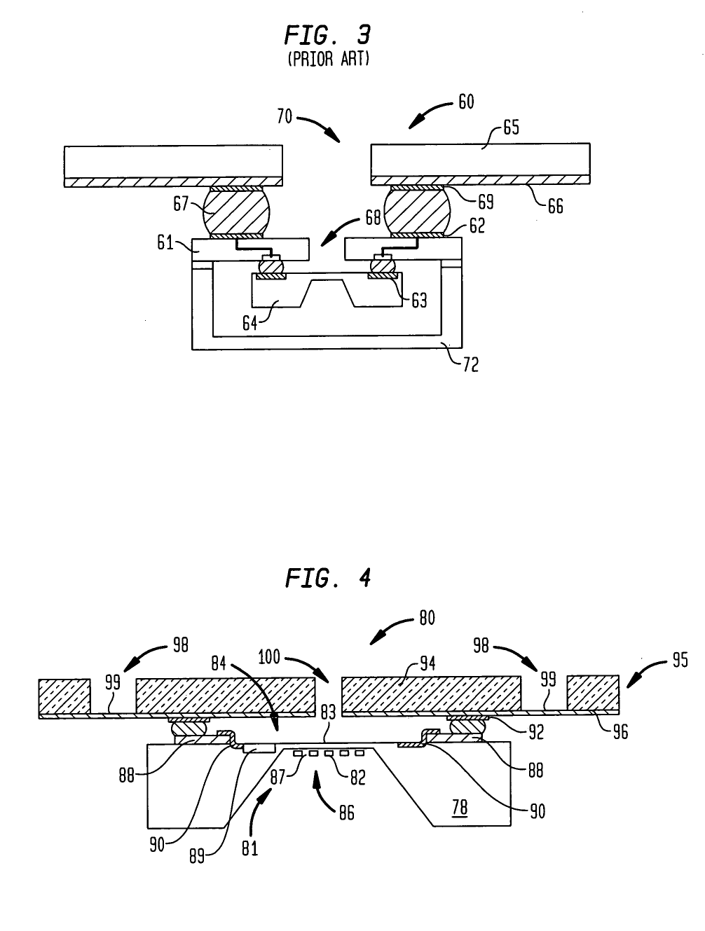

In yet other variations of the embodiments described above with respect to FIGS. 1-11, the chip can include other types of MEMS devices, especially those that require one of the faces, e.g., a front face, of the device to be exposed to an opening, while also requiring a cavity adjacent to the other face, e.g., a rear face, of the chip 210. Examples of such devices include pressure sensors and microfluidic devices.

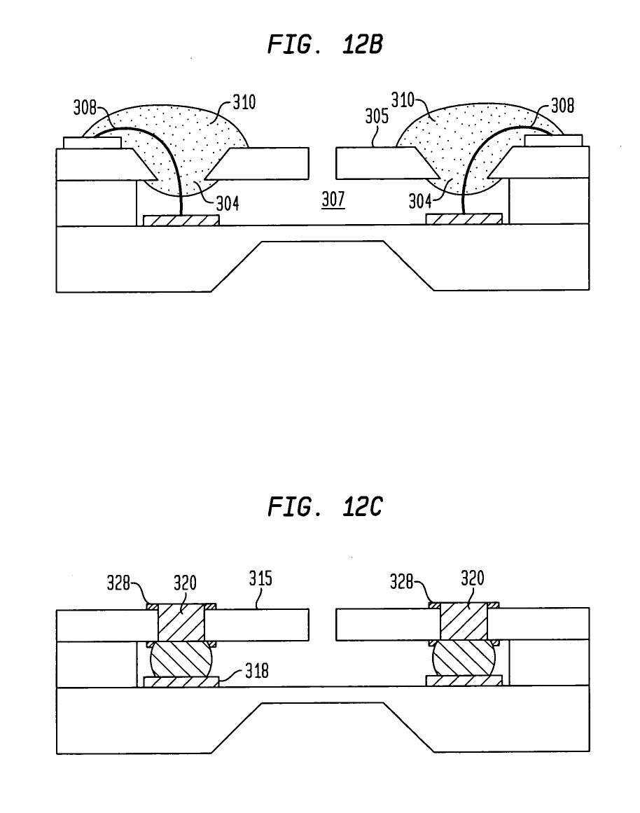

FIG. 12A illustrates another embodiment of the invention in which a unit 300 including an acoustic transducer chip 210 has a structure in which conductive interconnects 302 to the chip 210 are disposed in a plurality of through holes 304 of a cover element such as a lid 305. In the example shown in FIG. 12A, the conductive interconnects of the unit 300 include a fusible material such as solder extending from the bond pads 318 on the front surface 303 of the chip 210 bond pads through the through holes 304. Such structure also includes a perimeter seal, which can be referred to as a “picture frame ring seal” when viewed in a plan view, the ring seal enclosing the active area 306 of the chip 210 and the conductive interconnects 302. Various structures and methods of forming such structures are disclosed in U.S. patent application Ser. No. 10/949,674, filed Sep. 24, 2004. This application is hereby incorporated by reference herein. In particular, the incorporated application describes many alternative ways of forming structures, including various ways of forming the conductive interconnects, cover elements, caps and lids, and ring seals of the structures. In this case, the seal need not be hermetic.

Unit 300 varies from the structures disclosed in the incorporated application referenced above in that an acoustic port or opening 307 is provided which extends through lid 305 to allow passage of acoustic energy, e.g., a pressure wave through the opening. FIG. 12B shows a further embodiment in which wire bonds 308 are provided which extend through the through holes 304 of the lid 305, instead of soldered conductive interconnects as shown in FIG. 12A. In this case, in order to better control the characteristics of the acoustic port 307, the through holes 304 are preferably plugged with a sealing material such as an organic encapsulant which is used to encapsulate the wire bonds 308.

In a further embodiment as shown in FIG. 12C, a lid 315 is joined to the chip which is solid with the exception of the acoustic port. Such lid 315 is formed or procured as a flat plate that contains an array of solid or closed electrical through vias. Ceramic, glass and silicon are common materials from which the lid or plate 315 can be formed. The vias can be formed and filled by many methods including electroplating and thick film processes. Lands 328 may additionally be provided on the lid 315 in conductive contact with the vias 320. The vias in lid 315, having one via 320 in registration with each bond pad 318 on the chip 210, are bonded to the bond pads 318 through any of several well known techniques such as solder bumps, conductive stud bumps, conductive adhesives, thermo-compression and thermo-sonic bonding are materials and methods used in forming interconnects that may be augmented by conductive stud bumps or other mechanical features, as appropriate.

Alternatively, electrical interconnection between the bond pads and the lands 328 can be provided by mechanically compliant structures, examples of which include Z-axis conductive adhesives, Z-axis conductive polymers, springs, fingers, plungers and the like. Z-axis conductive adhesives have an additional advantage in that a ring of material surrounding the bond pads 318 of the chip 210 can serve both the function of providing the interconnects and a material for providing a picture frame ring seal.

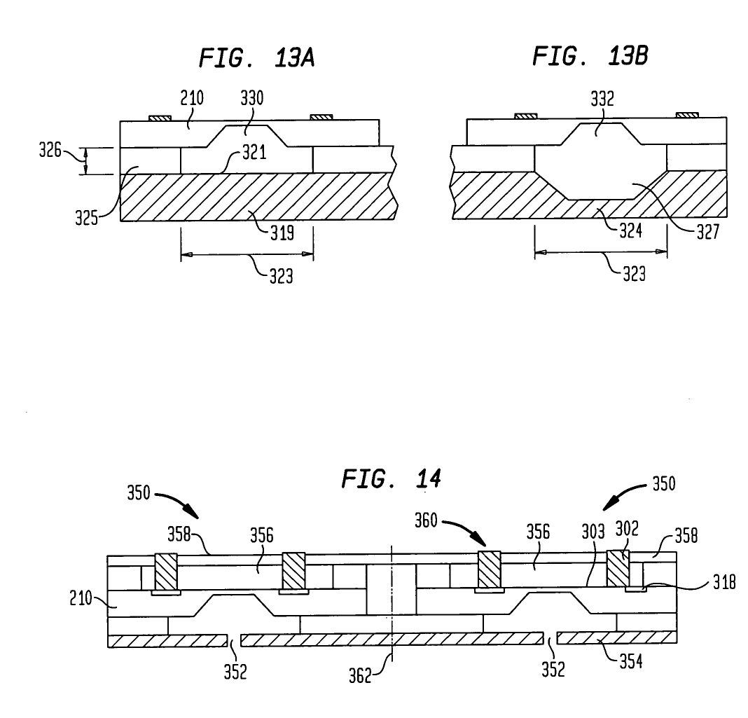

FIG. 13A is a sectional view illustrating an embodiment for providing the acoustic cavity of the transducer chip. The structure shown in FIG. 13A is intended to be joined to a cover element such as a lid to form lidded units as shown and described in the above embodiments with respect to FIGS. 12A-12C. As depicted therein, the chip 210 is mounted to a back plate 319 by a picture frame ring seal 325 such as that described above. The plate 319 has a flat major surface 321 which opposes the chip 210. In this case, the volume of the cavity 330 is determined by the dimensions 323 of the plate 319 inside the ring seal 325 and the thickness 326 of the ring seal.

On the other hand, in the embodiment shown in FIG. 13B, the back plate 324 includes a recess 327. As the recess 327 adds height to the cavity 332, when the lateral dimensions of the back plate 324 inside the ring seal are the same as those of plate 319 (FIG. 13A), the cavity 330 shown in FIG. 13B has greater volume than that shown in FIG. 13A. The recesses can be created by a variety of methods, of which chemical etching, electro-forming and mechanical forming are three possibilities, among others. When the back plate 324 is a metal, e.g., of aluminum or copper, the back plate 324 can additionally function as an electromagnetic shield, or form part of a Faraday cage for preventing electromagnetic waves traveling through free space, as excited by the acoustic transducer, from passing beyond the back plate 324. Alternatively, a back plate formed of silicon or other nonconductive or semiconductive material can be metallized to provide sufficient electrical conductivity for this purpose. In yet another alternative, the back plate need not be a single material, but instead can have a composite construction. In a particular example, the back plate is provided as a combination of a metal and a polymeric layer such as a tape-like circuit panel.

FIG. 14 illustrates yet another embodiment of a plurality of units 350, which remain attached to each other, such as in form of a wafer or other multiple units of chips. FIG. 14 illustrates a stage of fabrication after steps are conducted to form the attached units 350. This embodiment varies from the above-described embodiments in that the acoustic port 352 is provided in the back plates 354 of the units 350, and the acoustic cavities 356 are disposed between the lids 358 and the chips 210, which are still attached in wafer form, as shown. As best seen in FIG. 15, conductive interconnects 302 are provided which extend from bond pads 318 on the front surface 303 of the chip 210 through a plurality of through holes 360 in the lid 358.

After the units 350 are fabricated in wafer form to the stage shown in FIG. 14, the units 350 are severed along dicing channel 362 to form individual units, as shown. FIG. 15 illustrates one such individual packaged unit 350, after conductively bonding the interconnects 302 to terminals 366 of a circuit board 364, such as through solder balls 365 as shown.

In further variations of the embodiments shown in FIGS. 13A-B and FIGS. 14 and 15, further increases in the volume of the cavity can be achieved if particular interconnect structures are utilized which are capable of providing a greater spacing 325 between the back plate 319 or 324 and the chip 210, (FIGS. 13A-B), or a greater spacing 335 between the chip 210 and the lid 358 (FIGS. 14-15). For example, conductive balls having a core of copper or polymer can be used to increase the spacing of the interconnect. Fuzz buttons, micro-post stud bumps, springs and Z-axis conductive polymers are examples of elements that can be used to provide conductive interconnections across gaps and to provide mechanical compliance, as well.

FIG. 16 illustrates another embodiment in which a unit 400 has a construction similar to unit 80 (FIG. 4), i.e., having a chip 402 electrically interconnected to a package element 404, e.g., circuit board or flexible circuit panel such as a tape, which includes a dielectric element and a patterned metal layer. The unit 400 is mounted within a recess of a dielectric housing 406, with a front face 403 of the chip 402 facing upward. Housings similar to that shown in FIG. 16 are commonly provided of ceramic materials, or alternatively, as laminated dielectric elements having a plurality of layers of dielectric material such as FR-4 type epoxy-reinforced fiberglass. However, conventionally provided housings are inadequate to meet the requirements of packaging a chip according to this embodiment of the invention. Such housings neither provide sufficient electromagnetic shielding, nor do they provide an enclosed cavity or acoustic port. Nor are conventional housings capable of permitting interconnection to a circuit board with either the top or the bottom of the unit facing the circuit board.

As shown in FIG. 16, the recess within the housing 406, as sealed by lid 410, encloses a cavity 408 adjacent to a front face 403 of the acoustic transducer chip 402. The recess has a lateral dimension 412 and a vertical dimension 414, which together with a transverse dimension (perpendicular to the view shown in FIG. 13), define the enclosed volume of the cavity. The housing 406 further has a through hole 424 extending from a bottom edge 420, which is connected to an acoustic port 422 adjacent to the rear face 405 of the chip.

The embodiment shown in FIG. 16 provides gull-wing style leads 418 extending from edges 416 of the housing, the leads 418 facilitating further interconnection to a circuit board in a manner such as that shown and described above with respect to FIG. 1. In particular, the gull leads 418 facilitate interconnection to a circuit board with the bottom edge 420 of the housing facing the circuit board, when the circuit board includes an opening in registration with the through hole 424. Alternatively, the gull leads 418, which bend, permit the assembly shown in FIG. 16 to be mounted to a circuit board such that the lid 410 faces down and the through hole 424 faces away from the circuit board.

As particularly shown in FIG. 16, the unit 400 is electrically interconnected to internal contacts 426 provided on a shelf 428 of the housing 406, by conductive masses, e.g. solder masses, or a conductive adhesive, or other means, such as one or more of the mechanically compliant elements discussed above. The contacts 426, in turn, are conductively connected to the gull leads 418 through vias 430 and internal traces 432 within the housing.

To provide a good seal to enclose cavity 408, a sealing material such as a polymeric material, or alternatively, one of the conductive masses discussed above can be disposed as a fillet 436 to bridge the gap between the interior walls of the housing 406 and the package element 404. Likewise, a sealing material is desirably disposed between front surface 403 of the chip and the package element 404, in addition to the bonding material 438 that conductively interconnects the chip 402 to the package element 404.

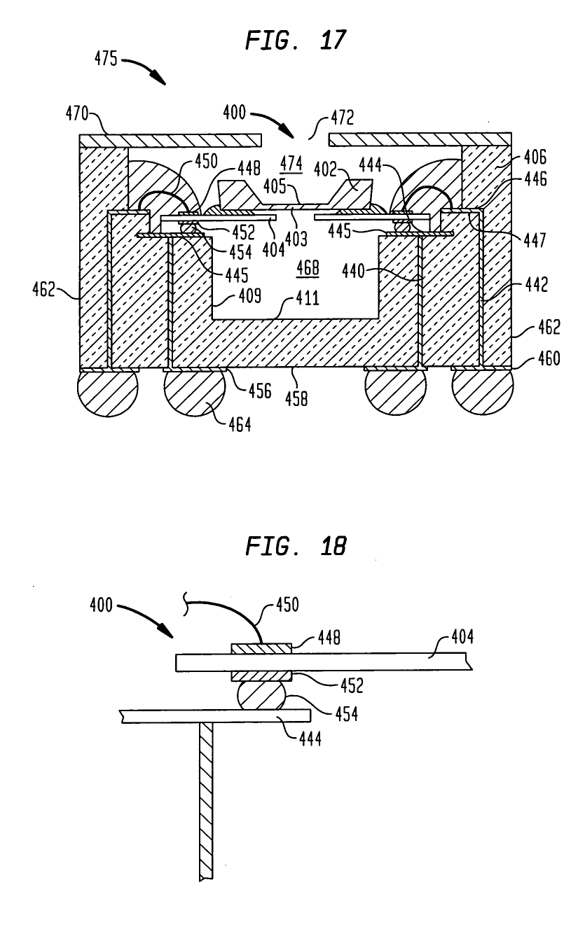

FIG. 17 illustrates a variation of the embodiment shown in FIG. 16 in which unit 400 is mounted in an assembly 475, with the front face 403 of the acoustic transducer chip 402 facing down towards a recess of a housing 406. This orientation results in the cavity 468 being provided between the front face 403 and interior walls 409 and bottom 411 of the housing. The bottom face 405 of the chip 402 is exposed within acoustic port 474 at the top surface of the housing 406, which is covered by lid 470 having through hole 472.

In the variation shown in FIG. 17, the housing 406 includes a set of lower contacts 444 provided on a lower interior shelf 445 of the dielectric housing and a set of upper contacts 446 provided on an upper interior shelf 447 of the housing. As best seen in FIG. 18, which is a partial sectional view of the structure shown in FIG. 17, unit top contacts 448 of the unit 400 are electrically connected to the upper contacts 446 (FIG. 17) of the housing, such as through wire bonds 450, as shown, and unit bottom contacts 452 are electrically connected to the lower contacts 444, such as through a fusible conductive material, e.g., solder bonds 454. From the lower contacts 444, a set of inner vias 440 extend downwardly to a set of inner bottom contacts 456 formed on a bottom edge 458 of the housing 406. A set of outer vias 442 extends downwardly from the upper contacts 446 to outer bottom contacts 460. The outer bottom contacts 460 are disposed on the bottom edge 458 of the housing 406, but at locations which are closer to the outside peripheral edges 462 of the housing 406 than the inner bottom contacts 456. In the particular embodiment shown in FIG. 17, solder bumps 464 are provided on the inner and outer bottom contacts. However, since the assembly 475 including the unit 400 mounted to housing 406 can be interconnected by other methods, a thin layer of solder or other conductive feature, e.g., micro-post, fuzz button, mechanically compliant feature, etc., can be utilized to further interconnect the assembly 475 to an element such as a circuit board in a higher-level assembly, in place of the solder bumps 464 that are disposed on the inner and outer bottom contacts.

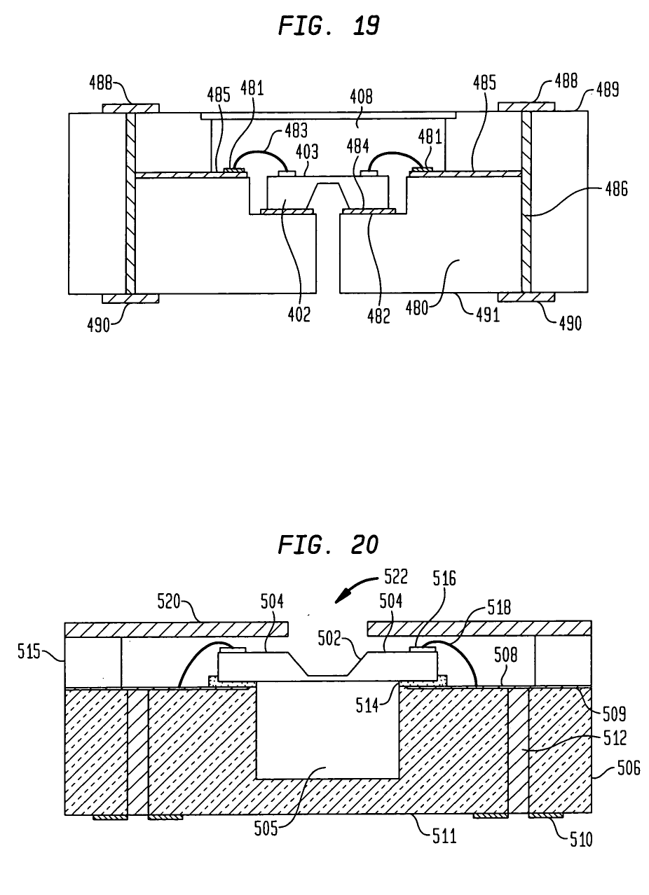

FIG. 19 illustrates a variation of the embodiment shown in FIG. 16, in which the acoustic transducer chip 402 is mounted with the front face 403 facing upwardly within the housing 480. The chip is mounted by a die attach adhesive 484 directly to a first ledge 482 of the housing, such that the cavity 408 is disposed adjacent to the front face 403. Wire bonds 483 conductively interconnect the chip to chip contacts 481, which are connected to traces 485 provided on a second ledge of the housing 480. Traces 485, in turn, are connected to conductive through vias 486 which extend between top contacts 488 provided on a top surface 489 of the housing and bottom contacts 490 provided on a bottom surface 491 of the housing.

FIG. 20 illustrates a further embodiment in which an acoustic transducer chip 502 is mounted to a package element 506 containing a cavity 505, as by a die attach adhesive 514. A lid 520, preferably consisting essentially of a metal, is sealed by a sealing material 515 or otherwise attached to the housing to overlie the chip 402, the lid having an opening 522 for permitting passage of acoustic energy through the lid 520. Because of its metallic composition, the lid functions as a portion of a Faraday cage or electromagnetic shield to protect against radiative propagation of electromagnetic waves through free space. In this embodiment, the package element 506 includes internal vias 512 which connect to top contacts 508 and bottom contacts 510 formed on contact-bearing top and bottom surfaces 509, 511, of the package element, respectively. Chip 502 includes bond pads 516 disposed on a rear face 504 of the chip. The bond pads are electrically interconnected to the top contacts 508 on the package element 506, such as by wire-bonds 518, as shown. Other conductive interconnect methods include lead bonding.

In an alternative embodiment, as shown in the inset of FIG. 21, interconnection between the chip 502 and the housing 506 can be provided through a patterned metal layer of a lid 530 which also includes a dielectric layer 532, the chip being bonded to the lid 530, e.g., by way of solder balls 531 or a conductive adhesive or mechanically compliant structure forming conductive interconnects from contacts 528 on the front surface 503 of the chip to contacts 529 of the lid, to name only a few possible ways. A die attach 514 is provided to attach the rear surface of the chip to the package element 506. In one case, leads 534 of the lid 530 are deformably bonded to the top contacts 508 of the package element 506, as by a bonding tool which presses the leads downwardly through bond windows provided in the lid to bond the leads 534 to the top contacts 508.

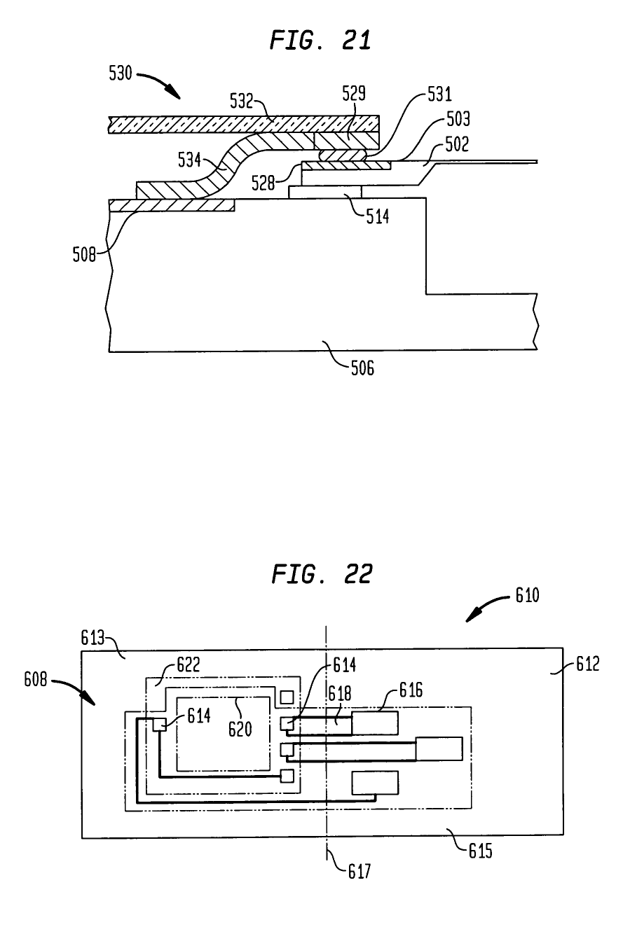

A method of packaging a chip according to another embodiment of the invention will now be described, with reference to FIGS. 22 through 27. Referring to FIGS. 22 and 23, a flexible package element or “chip carrier” 610 is provided. FIG. 22 is a plan view of the flexible chip carrier 610 looking toward a metal layer 612 of the chip carrier 610. FIG. 23 is a cross-sectional view. The flexible chip carrier 610 is typically provided as a unit of an elongated flexible tape such as that described above with reference to FIG. 4. The chip carrier 610 includes an upper portion 613 for placement adjacent to a front face 632 (FIG. 24) of a chip 622, and a lower portion 615 for placement adjacent to a rear face 634 (FIG. 24) of the chip.

Similar to the embodiment described above with respect to FIGS. 8A-B, the chip carrier 610 is intended to be folded along a fold line 617 which divides the upper portion 613 from the lower portion 615. The metal layer 612 includes a plurality of bond pads 614 for electrical connection to a chip 622, a plurality of lower terminals 616 for external connection, such as to a circuit panel, and a plurality of traces 618 extending between the bond pads and the lower terminals. The metal layer desirably includes a ground plane 608 which extends over as much area of the dielectric layer 611 as possible, to provide electromagnetic shielding from radio frequency energy, while maintaining separation from the bond pads 614, terminals 616, and traces 618 of the metal layer 612.

Referring to FIG. 24, the metal layer 612 includes an opening 620 which is sized and aligned to leave exposed an active area 628 of the chip after mounting the chip to the chip carrier 610.

The chip 622 has a front face 632 on which an active area 628 is disposed. Preferably, the active area includes a device or set of devices which receive electromagnetic signal energy: for example, optical wavelength signal energy, through free space or other medium without wires from a space outside the chip carrier 610, and/or which transmit electromagnetic energy to such space. Preferably, the device includes an image signal transducer such as a charge-coupled device (CCD) array. Alternatively, the device includes an image signal output device such as a liquid crystal display array or thin film transistor (TFT) array, or non-imaging signal output device such as a light-emitting diode (“LED”) or a semiconductor laser. In still another embodiment, operation of the device is alterable by energy incident upon the active area 628. For example, the active area 628 can include an erasable programmable read only memory which is erasable upon irradiation by ultra-violet light (UV-EPROM). In yet another example, the active area can include one or more fuses which are fusible upon application of light, e.g., laser light, having a sufficiently confined beam spot and sufficient energy.

In the embodiment shown in FIG. 24, the chip 622 is mounted to the chip carrier 610 by a flip-chip attach technique. According to such technique, contacts 624 disposed on the front face 632 of the chip 622 are bonded to the bond pads 614 of the chip carrier. Various ways exist for making such bonds. Preferably, gold stud bumps (not shown) are first formed on the contacts 624, which are typically formed of aluminum, while the chip 622 is still attached to other chips 622 in wafer form. A conductive adhesive 626 is then applied to the stud bumps or to bond pads 614, after which the contacts 624 are adhesively bonded to the bond pads 614. This initial bonding process is typically followed by subsequent curing, which can be performed either at room temperature, or preferably, at a moderately low temperature above room temperature. Alternatively, according to other well-known methods, solder balls containing a eutectic composition, tin or a combination of solder and tin are formed on the contacts 624 of chips 622 while the chips 622 are still attached on a wafer. Thereafter, the chips are severed, and an individual chip 622 is bonded to the chip carrier 610 by heating the chip 622 to soften the solder balls at a relatively low temperature, and then aligning and contacting the chip 622 to the chip carrier 610.

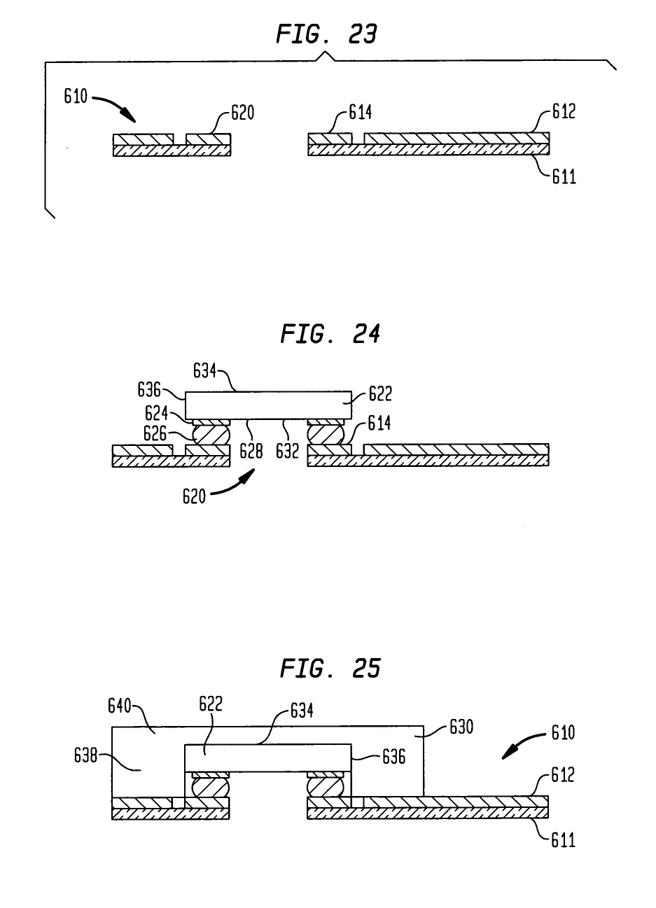

Thereafter, as illustrated in FIG. 25, a molding 630 is provided. The purpose of the molding 630 is to support the chip 622 and to buffer the chip against strain due to mismatch between the CTE of the chip and that of a circuit panel to which the chip carrier will be attached. While the chip is not required to be hermetically sealed when the packaging process is completed, the molding preferably provides at least some protection against contaminants reaching the active area 628 (FIG. 24). In the embodiment shown in FIG. 25, the molding includes side portions 638 disposed adjacent to the peripheral edges 636 of the chip and also includes a rear portion 640 disposed behind the rear face 634 of the chip. Alternatively, the molding may be provided as a “picture frame” element having only side portions 638 disposed adjacent to the four peripheral edges of the chip, while leaving the rear face 634 of the chip uncovered by the molding.

Various ways exist for providing a molding having suitable characteristics. The molding is desirably formed of a compliant material which allows for differential expansion of the chip relative to a circuit panel to which the packaged chip is connected. In one embodiment, the molding is formed separately from the process by which the chip is attached to the chip carrier, and is placed over the rear face of the chip after the chip is mounted to the chip carrier. In another embodiment, the molding is molded in place from a mass of encapsulating material after the chip is mounted to the chip carrier.

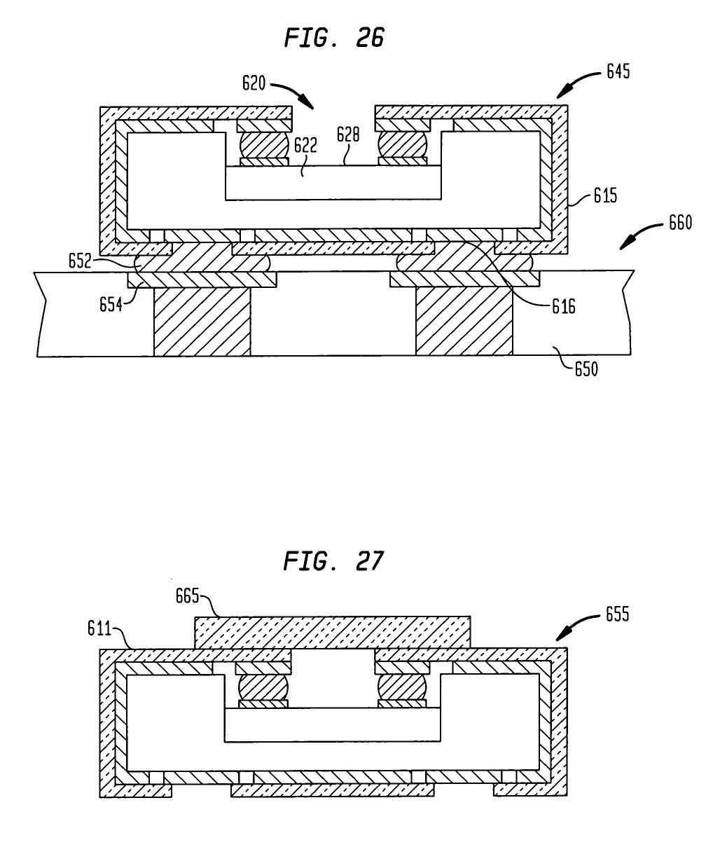

After the molding is provided, in a further processing step as shown in FIG. 26, the flexible chip carrier 610 is folded around the molding, such that the lower portion 615 of the chip carrier now underlies the rear face 634 of the chip 622 to provide a packaged chip 645. With the chip carrier 610 thus folded, lower terminals 616 of the lower portion 615 of the metal layer are now exposed for external connection to another element such as a circuit panel 650. The lower terminals 616 are then bonded to terminals 654 of the circuit panel 650 by way of a conductive adhesive 652 or solder, for example, to form an assembly 660 including the packaged chip 645 as mounted to the circuit panel 650.

When the active area 628 of the chip 622 includes an acoustic transducer such as a microphone, loudspeaker or piezoelectric device, the opening 620 in the metal layer above the active area is desirably left uncovered to permit the transmission of the acoustic energy to and/or from the chip. Accordingly, the packaged chip or an assembly including the packaged chip can be placed in use without specific additional encapsulation over the active area 628 of the chip.

As shown in FIG. 27, when the active area includes an image signal transducer or other electromagnetic signal transducer, or other device having elements that are sensitive to contamination by particles, a cover member 665 is provided as an element of a package 655 including such chip 622. The polyimide layer 611 of the chip carrier 610 has an adhesive quality. Accordingly, the cover member 665 adheres to polyimide layer 611 without requiring a separate adhesive. However, an adhesive can be applied to the polyimide layer 611 prior to placing the cover member 665 thereon for still better adhesion, if desired. The cover member 665 is substantially transparent to energy at a frequency or wavelength of interest to the operation of the image signal transducer or other device. The material of the cover element 665 is selected depending upon the spectral range of the energy required to be passed. Thus, for example, when an image signal to be passed has wavelengths in a visible range of the electromagnetic spectrum, the cover member can be glass or quartz, which is substantially transparent to such visible wavelengths. On the other hand, when the image signal has wavelengths in an infrared part of the spectrum, the cover member may be provided of another material such as germanium, which is substantially transparent to infrared wavelengths of interest. When the energy to be passed is in the ultra-violet range, as in the example of the UV-EPROM, the cover member can be formed of silica, which is transparent to ultra-violet wavelengths of interest.

The cover member need not merely pass electromagnetic energy. The cover member can instead by shaped or otherwise formed so as to function as a lens, hologram, wavelength-selective filter or other optically-active element, for focusing energy onto the active area of the chip, for focusing energy output by the chip onto an external device (not shown) which is placed in proximity to the packaged chip 655, or for otherwise affecting the electromagnetic energy. The cover member is optionally provided with one or more additional coatings such as an anti-reflective coating and a scratch-resistant coating.

The bond between the chip 622 and contacts 614 (FIG. 24) of the chip carrier desirably permits some movement between these elements. The bond between cover member 665 and dielectric layer 611 desirably also permits some movement between these elements (FIG. 27). One or both of these features, as well as any additional movement allowed by flexure of dielectric layer 611, together permit sufficient movement between cover member 665 and chip 622 to compensate for differential thermal expansion of the chip and cover member.

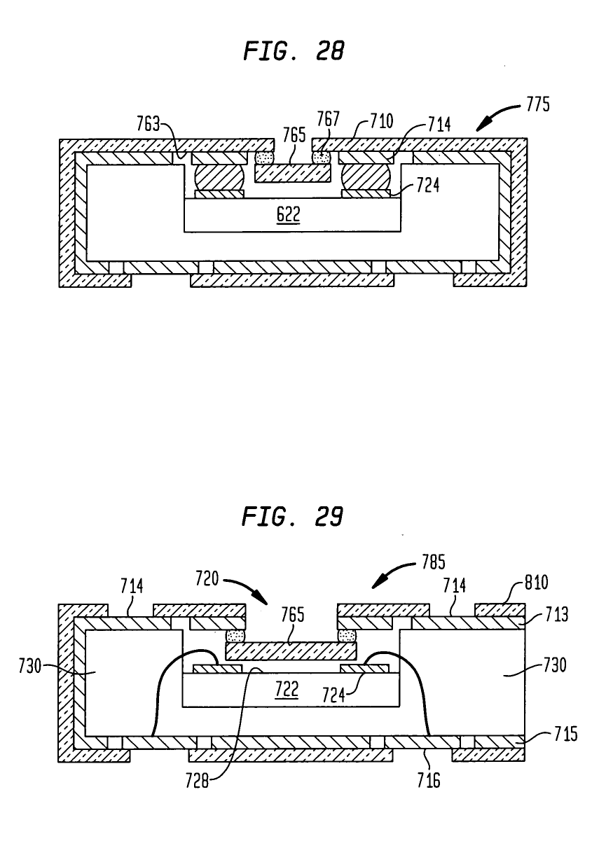

FIG. 28 illustrates an alternative embodiment of a packaged chip 775 in which a cover member 765 is provided on an inner side 763 of the polyimide layer 710 which faces toward the chip. Such placement is desirable when the packaged chip 775 is required to have a very low profile. In such embodiment, the cover member 765 is bonded to the inner side of the polyimide layer 710 by an adhesive 767. In such embodiment, the cover member is bonded to the chip carrier, followed by bonding the bond pads 724 of the chip 622 to the contacts 714 of the chip carrier.

FIG. 29 illustrates yet another embodiment of a low-profile package 785 in which the cover member 765 is bonded to the inner side of the chip carrier 810. Unlike the previously described embodiments, bond pads 724 of the chip 722 are wire-bonded to contacts 716 in the lower portion 715 of the metal layer. This embodiment also differs from the foregoing in its fabrication, in that the chip 722 is bonded to the lower portion 715 of the metal layer, as by an adhesive (not shown), and the cover member 765 is bonded to the upper portion 713 of the chip carrier. The chip carrier is then folded and the cover member 765 is aligned to the active area 728 of the chip 722, after which molding 730 is formed extending outwardly from the peripheral edges of the chip 722. The moldings can be formed by injecting a mass of encapsulant material between the upper and lower portions of the chip carrier, and thereafter, curing the mass. Connection to an external element such as a circuit panel is made through lower terminals 716, as shown and described above with respect to FIGS. 8A-B. The upper terminals can be used to mount additional devices such as further electronic devices to the assembly. Alternatively, connection to an external circuit panel is made through upper terminals 714, in which case a circuit panel mounted thereto (not shown) optionally has an opening sized and aligned to the opening 720 in the chip carrier 810 for transmission of energy to and/or from the chip. In this arrangement, flexure of the package substrate, such as flexing at the fold, further mechanically decouples the chip 722 from the cover member 765.

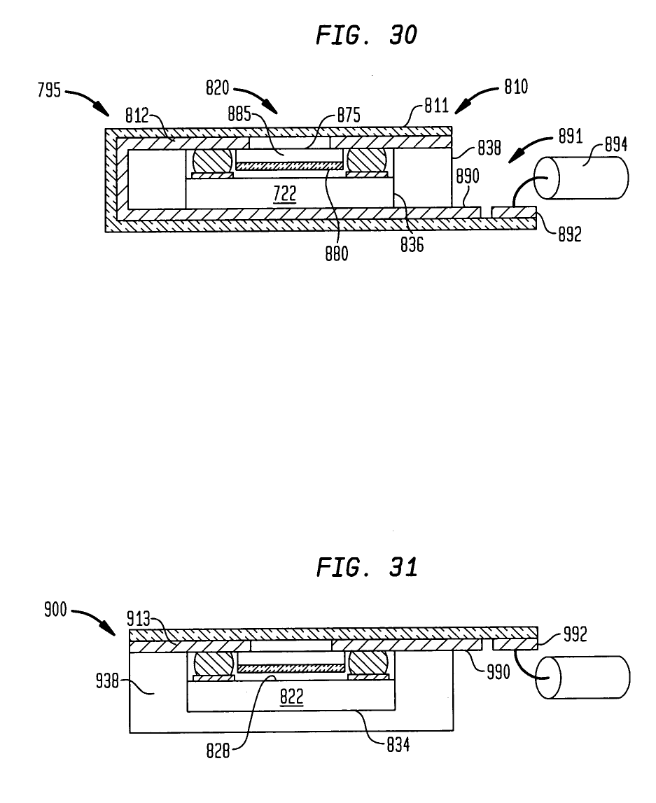

FIG. 30 illustrates an embodiment of a low-profile packaged chip 795 adapted to receive an X-ray or gamma ray image signal arriving from a space above an opening 820 in a metal layer 812 of a chip carrier 810. In this embodiment, the polyimide layer 811 of the chip carrier covers the opening 820 in the metal layer. Polyimide is transparent to wavelengths in the X-ray range of the spectrum, such that the polyimide layer 811 fulfills the function of the cover member of other embodiments described above as a way of protecting the active area of the chip 722 from contamination by particles or chemicals. Typically, the chip 722 is most responsive to an imaging signal in visible and/or near-visible wavelengths in the infrared or ultraviolet ranges of the spectrum. For that reason, the package in which the chip is mounted is required to be optically opaque, as well, such that optical wavelength light from outside the package is blocked from transmission onto the chip. The polyimide layer fulfills this function, as well. Mounted in close proximity to the chip 722 is a photo-scintillator element 875 having a layer 880 of photo-scintillator material disposed on a supporting layer 885 of material which is transparent to X-ray wavelengths of interest. Preferably, the photo-scintillator element is mounted to the metal layer 812 of the chip carrier by an adhesive (not shown), as in the manner described above with reference to FIG. 28. The photo-scintillator material is adapted to emit light having wavelengths of interest to operation of the chip 722 when X-ray radiation impinges on the photo-scintillator material. In turn, the chip 722 picks up the optical wavelength emissions of the photo-scintillator element 875 as a signal representative of the X-ray imaging signal.

Another feature of the embodiment illustrated in FIG. 30 is an extended portion 890 of the chip carrier 810 which extends beyond a peripheral edge 836 of the chip 722 and beyond an outer edge 838 of the molding. The extended portion includes one or more terminals 892 exposed at an inner side 891 of the dielectric layer, facing toward the chip 722. External connection can be made to the packaged chip through terminals 892. Such external connection can be made to the terminals 892 through a conductor of a cable 894 or other signal carrier bonded thereto, such as bonded by a conductive adhesive or solder. This positions the cable end within the vertical extent of the packaged chip 795, thus minimizing the height of the assembly. Alternatively, extended portion 890 of the chip carrier includes an elongated insulated tail conductor fashioned from the metal layer and optionally the polyimide layer of the chip carrier 890, the tail adapted to carry a signal to and/or from the chip 722.

FIG. 31 illustrates a variation of the embodiment described above with reference to FIG. 30. In this embodiment, the metal layer of the chip carrier 900 has only an upper portion 913 disposed adjacent to the active area 828 of the chip 822 but not a lower portion, as described above with reference to FIG. 30. An extending portion 990 extends from the upper portion 913 of the metal layer for permitting external connection to the packaged chip, eliminating the need for a lower portion of the metal layer to be folded around the molding 938 to underlie the rear surface 834 of the chip 822. The upper portion includes terminals 992 for connection from an inner side of the chip carrier which faces the chip 822. For medical, dental, and veterinarian applications, the molding 938 and/or additional molding material (not shown) are provided as a biologically compatible overmolding for both protecting against transfer of material to a patient, such as when the packaged chip is used for receiving a dental X-ray signal, and as a barrier against contamination of the chip 822 in such use or through fluids used to sterilize the packaged chip.

The particular connection between the chip and the chip carrier as described in the foregoing embodiments is merely illustrative, and can be accomplished through any suitable means.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised present without departing from the spirit and scope of the invention as defined by the appended claims.

1. A packaged chip, comprising:
a chip having a front face, and a rear face opposite said front face, said chip including a device at one of said front and rear faces, said device operable as a transducer of at least one of acoustic energy and electromagnetic energy, said chip further including a plurality of bond pads exposed at one of said front and rear faces; and
a package element including a dielectric element and a metal layer disposed on said dielectric element, said package element having an inner surface facing said chip and an outer surface facing away from said chip, said metal layer including a plurality of contacts exposed at at least one of said inner and outer surfaces, said contacts conductively connected to said bond pads, said metal layer further including a first opening for passage of the at least one of acoustic energy and electromagnetic energy in a direction of at least one of to said device and from said device.

2. A packaged chip as claimed in claim 1, wherein said package element is flexible, said flexible package element including a flexible dielectric element.

3. A packaged chip as claimed in claim 2, wherein said flexible dielectric element includes a second opening aligned to said first opening.

4. A packaged chip as claimed in claim 1, wherein said transducer has at least one of a pickup function, a loudspeaker function, and an accelerometer function.

5. A packaged chip as claimed in claim 4, wherein said acoustic transducer includes a piezoelectric device.

6. A packaged chip as claimed in claim 1, wherein said transducer includes a capacitor, said capacitor having first and second plates, wherein said first plate is movable by the acoustic energy in relation to the second plate.

7. A packaged chip as claimed in claim 2, wherein said package element includes a unitary metal sheet including said metal layer and a unitary portion, said metal layer further including traces extending from said contacts, said unitary portion at least substantially surrounding said contacts and said traces.

8. A packaged chip as claimed in claim 2, wherein said bond pads are exposed at said front face, said flexible package element being folded such that a top portion of said flexible package element overlies said front face of said chip and a bottom portion of said flexible package element underlies said rear face, wherein said contacts include bottom contacts exposed at said outer surface of said bottom portion, said flexible package element further including leads, said leads conductively connecting said bond pads to said bottom contacts.

9. An assembly including a packaged chip as claimed in claim 8, further comprising a circuit panel mounted to said bottom contacts.

10. The assembly as claimed in claim 9 wherein said circuit panel further comprises top contacts exposed at said outer surface of said top portion.

11. A packaged chip as claimed in claim 8, wherein said leads include wire bonds.

12. A packaged chip as claimed in claim 11, wherein said metal layer includes traces, said traces including lead portions integral with said bottom terminals.

13. A packaged chip as claimed in claim 8, further comprising a spacer element, said spacer element maintaining a spacing between said top portion and said bottom portion.

14. A packaged chip as claimed in claim 13, wherein said spacer element includes a compliant member bonded to said top portion and said bottom portion.

15. A packaged chip as claimed in claim 14, wherein said compliant member includes a portion underlying said rear face of said chip.

16. A packaged chip as claimed in claim 1, wherein said chip includes a plurality of peripheral edges extending between said front and rear faces and said package element includes an extended portion extending beyond a first of said peripheral edges, said extended portion having an inner surface facing toward said chip and an outer surface facing away from said chip, said extended portion including at least one contact exposed at said inner surface for permitting conductive interconnection to said chip.

17. A packaged chip as claimed in claim 1, wherein said contacts are exposed at said outer surface, said package element having a plurality of lands exposed at said inner surface and traces extending between said lands and said contacts, said packaged chip further comprising conductive interconnects extending between said bond pads and said lands.

18. A packaged chip as claimed in claim 17, wherein said packaged chip further comprises a metal can substantially enclosing said chip, said metal can bonded to said package element, such that said metal layer and said metal can form a cavity adjacent to one of said front face and said rear face of said chip, said metal layer together with said metal can functioning as an electromagnetic shield at a frequency of interest.

19. A packaged chip as claimed in claim 17, wherein said chip has peripheral edges extending between said front face and said rear face, said packaged chip further comprising a housing surrounding said peripheral edges of said chip, said housing having a bottom surface bonded to said inner surface of said package element, said packaged chip further comprising a metal lid overlying said chip, said metal lid bonded to a top surface of said housing, such that said housing and said metal lid enclose a cavity adjacent to one of said front face and said rear face.

20. A packaged chip, comprising:
a chip having a front face, a rear face opposite said front face, an acoustic transducer exposed at at least one of said front and rear faces, and a plurality of bond pads exposed at least one of said front and rear faces;
a package element having a plurality of through holes aligned to said bond pads, said package element mounted to cover one of said front and rear faces of said chip so as to define a cavity between said acoustic transducer and said package element, leaving exposed another one of said front and rear faces for passage of acoustic energy to or from said acoustic transducer in a direction normal to said front face; and
a plurality of electrically conductive interconnects extending at least partially through said through holes.

21. An assembly including a packaged chip as claimed in claim 22, further comprising a circuit panel having a plurality of terminals, said conductive interconnects conductively bonded to said terminals, such that said exposed one of said front and rear faces faces away from said circuit panel to permit passage of the acoustic energy to and from said acoustic transducer.

22. A packaged chip as claimed in claim 1, wherein operation of said device is alterable by the electromagnetic energy.

23. A packaged chip as claimed in claim 22, wherein the device includes an ultra-violet light erasable programmable read only memory (UV-EPROM), said UV-EPROM erasable by the electromagnetic energy.

24. A packaged chip as claimed in claim 22, wherein the device includes a fusible element permanently alterable by the electromagnetic energy.

25. A packaged chip as claimed in claim 1, further comprising a cover member aligned to said first opening, said cover member mounted to at least one of said inner surface and said outer surface, said cover member being substantially transparent to the electromagnetic energy.

26. A packaged chip as claimed in claim 25, wherein said cover member includes at least one of an anti-reflective member, a scratch-resistant member, and a lens.

27. A packaged chip as claimed in claim 25, wherein said metal layer is exposed at said inner surface of said package element, and said cover member is mounted to said metal layer.

28. A packaged chip as claimed in claim 1, wherein said device includes a first array of photosensitive elements, said packaged chip further comprising a photo-scintillator element aligned to said first opening, whereby said first array is operable to receive a first signal, said first signal representative of a second signal incident on said photo-scintillator element.

29. A packaged chip as claimed in claim 28, wherein said photo-scintillator element is disposed between said inner surface of said package element and said chip.

30. A packaged chip as claimed in claim 28, wherein the second signal includes X-ray wavelengths.

31. A packaged chip as claimed in claim 30, wherein said dielectric element at least substantially covers said first opening, said dielectric element being substantially transparent to the X-ray wavelengths and being substantially opaque to optical wavelengths.
